(19) United States
(12) Patent Application Publication
(10) Pub. No.: US 2025/0244413 A1
(43) Pub. Date: Jul. 31, 2025

(54) MANUFACTURING METHOD OF MAGNETIC SENSOR

(71) Applicant: TDK CORPORATION, Tokyo (JP)

(72) Inventors: Hirokazu TAKAHASHI, Tokyo (JP); Takashi Saito, Tokyo (JP)

(73) Assignee: TDK CORPORATION, Tokyo (JP)

(21) Appl. No.: 19/034,285

(22) Filed: Jan. 22, 2025

(30) Foreign Application Priority Data
Jan. 31, 2024 (JP) 2024-013568

(51) Int. Cl. G01R 33/00; G01R 33/09; H10N 50/10

(52) U.S. Cl. CPC G01R 33/0052; G01R 33/093; H10N 50/10; G01R 33/098

(57) ABSTRACT

A magnetic sensor includes at least one MR element and at least one magnetic field generator. The MR element includes a magnetization pinned layer and a free layer. The magnetic field generator includes a ferromagnetic portion and an antiferromagnetic portion to be exchange-coupled with the ferromagnetic portion. A manufacturing method of the magnetic sensor includes a process of forming the at least one magnetoresistive element and a process of forming the at least one magnetic field generator. The process of forming the magnetic field generator includes a process of forming at least one initial magnetic field generator including an initial ferromagnetic portion that later becomes the ferromagnetic portion and the antiferromagnetic portion, and a process of fixing a magnetization direction of the initial ferromagnetic portion so that the initial ferromagnetic portion becomes the ferromagnetic portion by using laser light and an external magnetic field.

### CROSS REFERENCE TO RELATED APPLICATIONS

This application claims the benefit of Japanese Priority Patent Application No. 2024-13568 filed on Jan. 31, 2024, the entire contents of which are incorporated herein by reference.

### BACKGROUND

The technology relates to a manufacturing method of a magnetic sensor configured to be capable of applying a bias magnetic field to a magnetoresistive element.

Magnetic sensors have been used for a variety of applications. For example, some magnetic sensors including a spin-valve magnetoresistive element provided on a substrate may be applied for some applications. The spin-valve magnetoresistive element includes a magnetization pinned layer whose magnetization is pinned in a certain direction, a free layer whose magnetization direction is variable depending on the direction of a target magnetic field, and a gap layer disposed between the magnetization pinned layer and the free layer.

U.S. Patent Application Publication No. 2015/0177285 A1 and U.S. Patent Application Publication No. 2016/0282144 A1 disclose a magnetic sensor including a magnetoresistive element and two magnetic field generators disposed with the magnetoresistive element interposed therebetween.

In some cases, there is a demand for a magnetic sensor that is configured so that the magnetization direction of the free layer of one of two adjacent magnetoresistive elements is different from the magnetization direction of the free layer of the other of the two adjacent magnetoresistive elements.

### SUMMARY

A magnetic sensor manufactured by a manufacturing method according to one embodiment of the technology includes: at least one magnetoresistive element including a magnetization pinned layer, a direction of a magnetization of the magnetization pinned layer being pinned in a certain direction, the magnetization including a component in a first direction, and a free layer whose a magnetization direction is variable depending on a target magnetic field, the target magnetic field being a magnetic field to be detected; and at least one magnetic field generator including a ferromagnetic portion including a ferromagnetic material, a direction of a magnetization of the ferromagnetic portion being fixed in a certain direction, the magnetization including a component in a second direction different from the first direction, and an antiferromagnetic portion including an antiferromagnetic material and exchange-coupled with the ferromagnetic portion, the at least one magnetic field generator being configured to generate a magnetic field to be applied to the at least one magnetoresistive element. The manufacturing method of the magnetic sensor according to one embodiment of the technology includes a process of forming the at least one magnetoresistive element, and a process of forming the at least one magnetic field generator. The process of forming the at least one magnetic field generator includes a process of forming at least one initial magnetic field generator including an initial ferromagnetic portion that later becomes the ferromagnetic portion and the antiferromagnetic portion, and a process of fixing a magnetization direction of the initial ferromagnetic portion so that the initial ferromagnetic portion becomes the ferromagnetic portion by using laser light and a first external magnetic field including a component in a first magnetic field direction.

Other and further objects, features, and advantages of the technology will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a magnetic sensor device including a magnetic sensor according to a first example embodiment of the technology.

FIG. 2 is a functional block diagram showing a configuration of the magnetic sensor device in the first example embodiment of the technology.

FIG. 3 is a circuit diagram showing a circuit configuration of the magnetic sensor according to the first example embodiment of the technology.

FIG. 4 is a perspective view showing a part of a first detection circuit in the first example embodiment of the technology.

FIG. 5 is a plan view showing a part of the first detection circuit in the first example embodiment of the technology.

FIG. 6 is a plan view showing a part of a second detection circuit in the first example embodiment of the technology.

FIG. 7 is a plan view showing a main part of the magnetic sensor according to the first example embodiment of the technology.

FIG. 8 is a cross-sectional view showing a part of a cross section at a position indicated by an 8-8 line in FIG. 7.

FIG. 9 is a plan view showing one process in a manufacturing method of the magnetic sensor according to the first example embodiment of the technology.

FIG. 10 is a plan view showing a process following FIG. 9.

FIG. 11 is a plan view showing a process following FIG. 10.

FIG. 12 is a plan view showing a process following FIG. 11.

FIG. 13 is a plan view showing a process following FIG. 12.

FIG. 14A is a plan view showing a second example of an arrangement of a resistor section and a magnetization direction of a ferromagnetic portion of a magnetic field generator in the first example embodiment of the technology.

FIG. 14B is a plan view showing a third example of the arrangement of the resistor section and the magnetization direction of the ferromagnetic portion of the magnetic field generator in the first example embodiment of the technology.

FIG. 14C is a plan view showing a fourth example of the arrangement of the resistor section and the magnetization direction of the ferromagnetic portion of the magnetic field generator in the first example embodiment of the technology.

FIG. 15A is a plan view showing a fifth example of the arrangement of the resistor section and the magnetization direction of the ferromagnetic portion of the magnetic field generator in the first example embodiment of the technology.

FIG. 15B is a plan view showing a sixth example of the arrangement of the resistor section and the magnetization direction of the ferromagnetic portion of the magnetic field generator in the first example embodiment of the technology.

FIG. 15C is a plan view showing a seventh example of the arrangement of the resistor section and the magnetization direction of the ferromagnetic portion of the magnetic field generator in the first example embodiment of the technology.

FIG. 16A is a plan view showing an eighth example of the arrangement of the resistor section and the magnetization direction of the ferromagnetic portion of the magnetic field generator in the first example embodiment of the technology.

FIG. 16B is a plan view showing a ninth example of the arrangement of the resistor section and the magnetization direction of the ferromagnetic portion of the magnetic field generator in the first example embodiment of the technology.

FIG. 16C is a plan view showing a tenth example of the arrangement of the resistor section and the magnetization direction of the ferromagnetic portion of the magnetic field generator in the first example embodiment of the technology.

FIG. 17A is a plan view showing an eleventh example of the arrangement of the resistor section and the magnetization direction of the ferromagnetic portion of the magnetic field generator in the first example embodiment of the technology.

FIG. 17B is a plan view showing a twelfth example of the arrangement of the resistor section and the magnetization direction of the ferromagnetic portion of the magnetic field generator in the first example embodiment of the technology.

FIG. 18 is a cross-sectional view showing a main part of a first modification example of the magnetic sensor according to the first example embodiment of the technology.

FIG. 19 is a cross-sectional view showing a main part of a second modification example of the magnetic sensor according to the first example embodiment of the technology.

FIG. 20 is a cross-sectional view showing a main part of a third modification example of the magnetic sensor according to the first example embodiment of the technology.

FIG. 21 is a cross-sectional view showing a main part of a fourth modification example of the magnetic sensor according to the first example embodiment of the technology.

FIG. 22 is a cross-sectional view showing a main part of a fifth modification example of the magnetic sensor according to the first example embodiment of the technology.

FIG. 23 is a plan view showing a main part of a magnetic sensor according to a second example embodiment of the technology.

FIG. 24 is a cross-sectional view showing a part of a cross section at a position indicated by a 24-24 line in FIG. 23.

FIG. 25 is a plan view showing a main part of a magnetic sensor according to a third example embodiment of the technology.

FIG. 26 is a cross-sectional view showing a part of a cross section at a position indicated by a 26-26 line in FIG. 25.

FIG. 27 is a plan view showing one process in a manufacturing method of the magnetic sensor according to the third example embodiment of the technology.

FIG. 28 is a plan view showing a process following FIG. 27.

FIG. 29 is a plan view showing a process following FIG. 28.

FIG. 30 is a plan view showing a process following FIG. 29.

FIG. 31 is a cross-sectional view showing a main part of a modification example of the magnetic sensor according to the third example embodiment of the technology.

FIG. 32 is a plan view showing a main part of a magnetic sensor according to a fourth example embodiment of the technology.

FIG. 33 is a cross-sectional view showing a part of a cross section at a position indicated by a 33-33 line in FIG. 32.

FIG. 34 is a plan view showing a main part of a first modification example of the magnetic sensor according to the fourth example embodiment of the technology.

FIG. 35 is a cross-sectional view showing a main part of a second modification example of the magnetic sensor according to the fourth example embodiment of the technology.

FIG. 36 is a cross-sectional view showing a main part of a third modification example of the magnetic sensor according to the fourth example embodiment of the technology.

FIG. 37 is a perspective view showing a magnetic sensor system including a magnetic sensor according to a fifth example embodiment of the technology.

FIG. 38 is a circuit diagram showing a circuit configuration of the magnetic sensor according to the fifth example embodiment of the technology.

FIG. 39 is a perspective view showing a part of the magnetic sensor according to the fifth example embodiment of the technology.

FIG. 40 is a plan view showing a part of the magnetic sensor according to the fifth example embodiment of the technology.

FIG. 41 is a side view showing a part of the magnetic sensor according to the fifth example embodiment of the technology.

FIG. 42 is a plan view showing a main part of the magnetic sensor according to the fifth example embodiment of the technology.

FIG. 43 is a cross-sectional view showing a part of a cross section at a position indicated by a 43-43 line in FIG. 42.

FIG. 44 is a cross-sectional view showing a part of a cross section at a position indicated by a 44-44 line in FIG. 42.

### DETAILED DESCRIPTION

It is an object of the technology to provide a manufacturing method of a magnetic sensor that enables the magnetization direction of a free layer of at least one magnetoresistive element to be different.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. Note that the description is given in the following order.

### First Example Embodiment

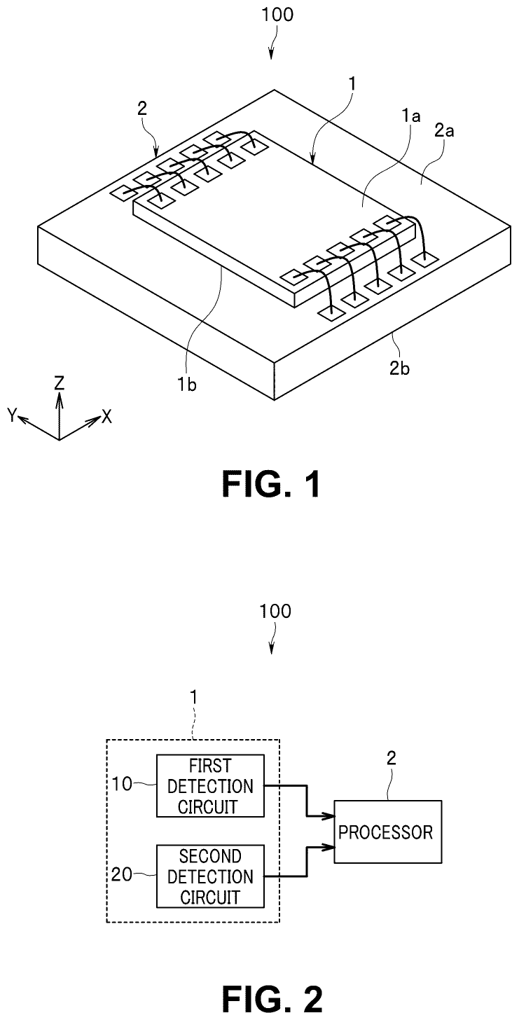

Initially, a configuration of a magnetic sensor device including a magnetic sensor according to a first example embodiment of the technology is described with reference to FIGS. 1 and 2. FIG. 1 is a perspective view showing the magnetic sensor device in the example embodiment. FIG. 2 is a functional block diagram showing a configuration of the magnetic sensor device in the example embodiment.

A magnetic sensor device 100 in the example embodiment includes a magnetic sensor 1 according to the example embodiment and a processor 2. The magnetic sensor 1 is configured to detect a target magnetic field, which is a magnetic field to be detected by the magnetic sensor 1, and to generate at least one detection signal. The magnetic sensor 1 may be a geomagnetic sensor that detects geomagnetism, a magnetic sensor for angle sensors or magnetic encoders that detect a rotating magnetic field, or a magnetic sensor for current sensors that detect a magnetic field generated by a current to be detected.

The processor 2 is configured to generate at least one detection value having a correspondence with the target magnetic field, based on at least one detection signal. The processor 2 is constituted, for example, by an application-specific integrated circuit (ASIC).

Each of the magnetic sensor 1 and the processor 2 is in a form of a chip having a rectangular parallelepiped shape. The magnetic sensor 1 includes a top surface 1a and a bottom surface 1b located on opposite sides of each other, and four side surfaces connecting the top surface 1a and the bottom surface 1b. The processor 2 includes a top surface 2a and a bottom surface 2b located on opposite sides of each other and four side surfaces connecting the top surface 2a and the bottom surface 2b. The magnetic sensor 1 is mounted on the top surface 2a of the processor 2 in such an orientation that the bottom surface 1b of the magnetic sensor 1 faces the top surface 2a of the processor 2. The magnetic sensor 1 is bonded to the processor 2 by adhesive, for example.

Here, X, Y, and Z directions are defined as shown in FIG. 1. The X, Y, and Z directions are orthogonal to one another. In the example embodiment, the Z direction is a direction perpendicular to the top surface 1a of the magnetic sensor 1 and from the bottom surface 1b of the magnetic sensor 1 to the top surface 1a. The directions opposite to the X, Y, and Z directions will be referred to as −X, −Y, and −Z directions, respectively.

Hereafter, the term “above” refers to positions located forward of a reference position in the Z direction, and “below” refers to positions located on a side of the reference position opposite from “above”. With respect to components of the magnetic sensor 1, the surface located at the end in the Z direction is referred to as “top surface,” and the surface located at the end of the −Z direction is referred to as “bottom surface. The expression “when viewed from a predetermined direction (e.g., the Z direction)” means that an object is viewed from a position away in the predetermined direction or in one direction parallel to the predetermined direction.

The magnetic sensor 1 includes a plurality of first pads (electrode pads) provided on the top surface 1a. The processor 2 includes a plurality of second pads (electrode pads) provided on the top surface 2a. In the magnetic sensor 1, of the plurality of first pads and the plurality of second pads, two corresponding pads are connected to each other by a bonding wire.

The magnetic sensor 1 includes a first detection circuit 10 and a second detection circuit 20. The first and second detection circuits 10 and 20 and the processor 2 are connected via the plurality of first pads, the plurality of second pads, and the plurality of bonding wires.

Each of the first and second detection circuits 10 and 20 includes a plurality of magnetic detection elements. In the example embodiment in particular, the plurality of magnetic detection elements are a plurality of magnetoresistive elements. Magnetoresistive elements will hereinafter be referred to as MR elements.

The first detection circuit 10 detects a component in a direction parallel to the X direction of the target magnetic field and generates at least one first detection signal having a correspondence with this component. The second detection circuit 20 detects a component in a direction parallel to the Y direction of the target magnetic field and generates at least one second detection signal having a correspondence with this component.

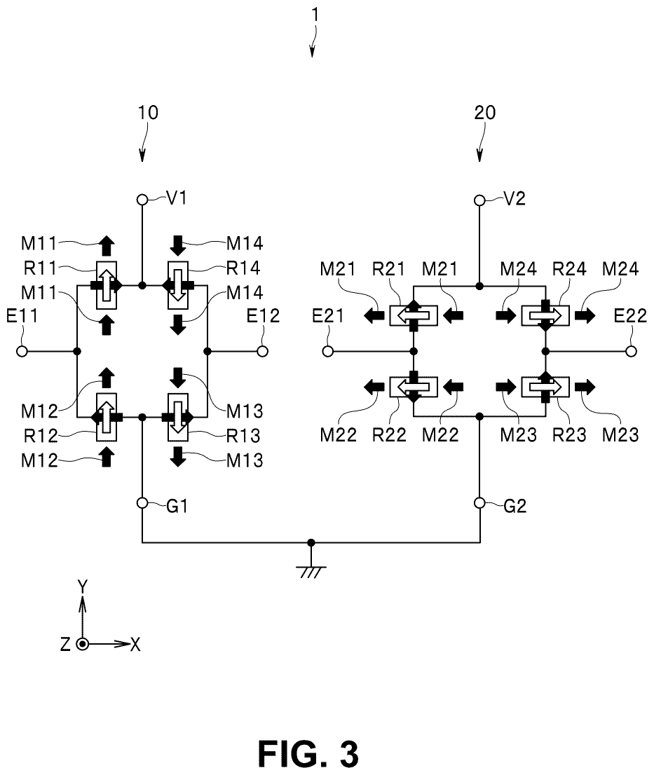

Next, a circuit configuration of the magnetic sensor 1 is described with reference to FIG. 3. FIG. 3 is a circuit diagram showing the circuit configuration of the magnetic sensor 1.

The first detection circuit 10 includes four resistor sections R11, R12, R13, and R14, a power supply port V1, a ground port G1, and two output ports E11 and E12. The resistor section R11 is provided between the power supply port V1 and the output port E11. The resistor section R12 is provided between the output port E11 and the ground port G1. The resistor section R13 is provided between the output port E12 and the ground port G1. The resistor section R14 is provided between the power supply port V1 and the output port E12. A voltage or current of a predetermined magnitude is applied to the power supply port V1. The ground port G1 is connected to ground.

The second detection circuit 20 includes four resistor sections R21, R22, R23, and R24, a power supply port V2, a ground port G2, and two output ports E21 and E22. The resistor section R21 is provided between the power supply port V2 and the output port E21. The resistor section R22 is provided between the output port E21 and the ground port G2. The resistor section R23 is provided between the output port E22 and the ground port G2. The resistor section R24 is provided between the power supply port V2 and the output port E22. A voltage or current of a predetermined magnitude is applied to the power supply port V2. The ground port G2 is connected to ground.

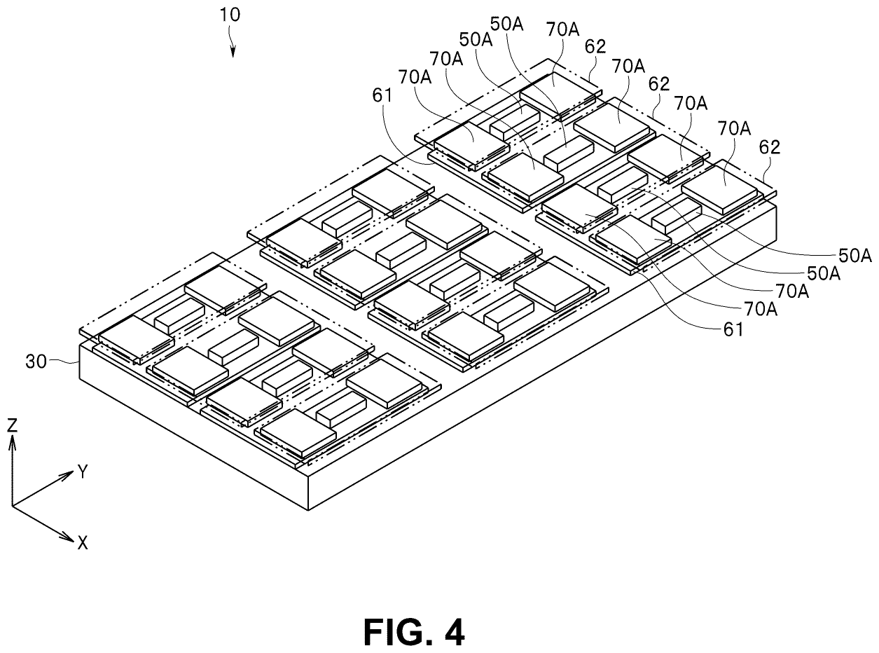

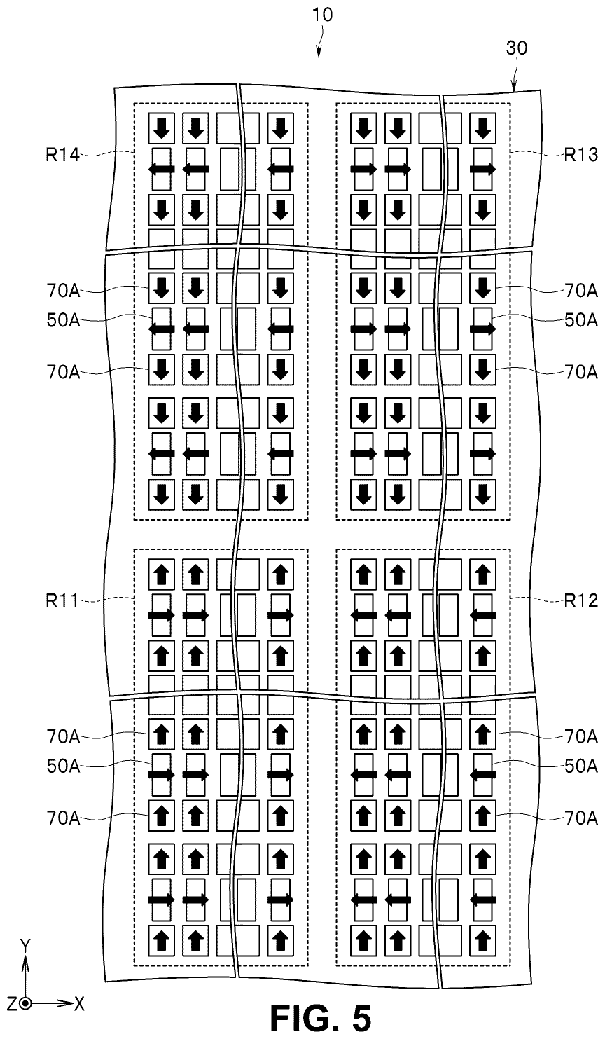

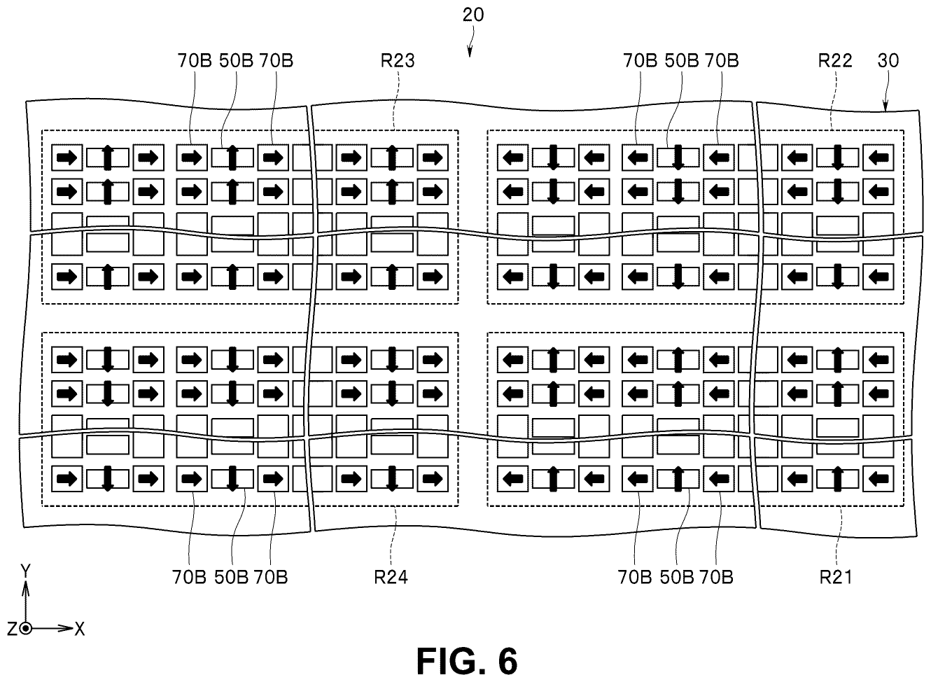

Next, respective configurations of the first and second detection circuits 10 and 20 are described with reference to FIGS. 4 through 6. FIG. 4 is a perspective view showing a part of the first detection circuit 10. FIG. 5 is a plan view showing a part of the first detection circuit 10. FIG. 6 is a plan view showing a part of the second detection circuit 20.

The magnetic sensor 1 further includes a substrate 30. The magnetic sensor 1 is constituted by forming, on the substrate 30, a plurality of components other than the substrate 30. The first detection circuit 10 and the second detection circuit 20 are provided on the substrate 30. Each of the resistor sections R11 to R14 includes a plurality of MR elements 50A. Each of the resistor sections R21 to R24 includes a plurality of MR elements 50B.

The plurality of MR elements 50A constituting the resistor section R11 are provided between the power supply port V1 and the output port E11 in circuit configuration. The plurality of MR elements 50A constituting the resistor section R12 are provided between the output port E11 and the ground port G1 in circuit configuration. The plurality of MR elements 50A constituting the resistor section R13 are provided between the output port E12 and the ground port G1 in circuit configuration. The plurality of MR elements 50A constituting the resistor section R14 are provided between the power supply port V1 and the output port E12 in circuit configuration.

The plurality of MR elements 50B constituting the resistor section R21 are provided between the power supply port V2 and the output port E21 in circuit configuration. The plurality of MR elements 50B constituting the resistor section R22 are provided between the output port E21 and the ground port G2 in circuit configuration. The plurality of MR elements 50B constituting the resistor section R23 are provided between the output port E22 and the ground port G2 in circuit configuration. The plurality of MR elements 50B constituting the resistor section R24 are provided between the power supply port V2 and the output port E22 in circuit configuration.

FIG. 5 shows a first example of an arrangement of the resistor sections R11 to R14 on the substrate 30. In this example, the resistor section R12 is disposed forward of the resistor section R11 in the X direction. The resistor section R13 is disposed forward of the resistor section R12 in the Y direction. The resistor section R14 is disposed forward of the resistor section R11 in the Y direction.

FIG. 6 shows a first example of an arrangement of the resistor sections R21 to R24 on the substrate 30. In this example, the resistor section R22 is disposed forward of the resistor section R21 in the Y direction. The resistor section R23 is disposed forward of the resistor section R22 in the −X direction. The resistor section R24 is disposed forward of the resistor section R21 in the −X direction.

Other examples of the arrangement of the resistor sections R11 to R14 and R21 to R24 on the substrate 30 will be described later.

Each of the resistor sections R11 to R14 further includes a plurality of lower electrodes 61 and a plurality of upper electrodes 62. As shown in FIG. 4, each of the plurality of lower electrodes 61 electrically connects two adjacent MR elements 50A in a direction parallel to the X direction. Each of the plurality of upper electrodes 62 electrically connects the two adjacent MR elements 50A disposed on two lower electrodes 61. The plurality of MR elements 50A arranged in a row in a direction parallel to the X direction are thereby connected in series.

Each of the resistor sections R11 to R14 further includes a plurality of connecting electrodes (not shown). In each of the resistor sections R11 to R14, the plurality of connecting electrodes electrically connect the plurality of lower electrodes 61 or the plurality of upper electrodes 62 so that a group of the plurality of MR elements 50A arranged in a row is connected in series. With such a configuration, each of the resistor sections R11 to R14 includes the plurality of MR elements 50A connected in series by the plurality of lower electrodes 61, the plurality of upper electrodes 62, and the plurality of connecting electrodes.

The above description of the connection relationship of the plurality of MR elements 50A is basically applicable also to the plurality of MR elements 50B of each of the resistor sections R21 to R24. In the above description of the connection relationship of the plurality of MR elements 50A, if the plurality of MR elements 50A, the X direction, and the Y direction are replaced with the plurality of MR elements 50B, the Y direction, and the X direction, respectively, a connection relationship of the plurality of MR elements 50B is described.

The magnetic sensor 1 further includes a plurality of magnetic field generators 70A and a plurality of magnetic field generators 70B. The plurality of magnetic field generators 70A include a plurality of pairs of the magnetic field generators 70A, each pair including two magnetic field generators 70A. The above two magnetic field generators 70A are disposed at a predetermined distance from each other in a direction parallel to the Y direction with one MR element 50A interposed therebetween. The two magnetic field generators 70A are configured to apply a bias magnetic field to the one MR element 50A located therebetween. The bias magnetic field is a part of the magnetic field generated by the magnetic field generator 70A, and includes a component parallel to the Y direction as a main component. At least the main component of the bias magnetic field is applied to the MR element 50A.

The plurality of magnetic field generators 70B include a plurality of pairs of the magnetic field generators 70B, each pair including two magnetic field generators 70B. The two magnetic field generators 70B are disposed at a predetermined distance from each other in a direction parallel to the X direction with one MR element 50B interposed therebetween. The two magnetic field generators 70B are configured to apply a bias magnetic field to the one MR element 50B located therebetween. The bias magnetic field is a part of the magnetic field generated by the magnetic field generator 70B, and includes a component parallel to the X direction as the main component. At least the main component of the bias magnetic field is applied to the MR element 50B.

As shown in FIG. 4, each of the plurality of magnetic field generators 70A may be interposed between the lower electrode 61 and the upper electrode 62. Although not shown, each of the plurality of magnetic field generators 70B may be interposed between the lower electrode 61 and the upper electrode 62.

In the example embodiment, each of the plurality of MR elements 50A and the plurality of MR elements 50B is a spin-valve MR element. The spin-valve MR element may include a magnetization pinned layer having a magnetization pinned in a certain direction, a free layer having a magnetization whose direction is variable depending on the direction and strength of the target magnetic field, and a gap layer disposed between the magnetization pinned layer and the free layer. The spin-valve MR element may be a TMR (tunnel magnetoresistive) element or may be a GMR (giant magnetoresistive) element. In the TMR element, the gap layer is a tunnel barrier layer. In the GMR element, the gap layer is a nonmagnetic conductive layer. The spin-valve MR element changes in resistance value depending on an angle that the magnetization direction of the free layer forms with respect to the magnetization direction of the magnetization pinned layer, and the resistance value is a minimum value when the angle is 0° and the resistance value is a maximum value when the angle is 180°. In each MR element, the free layer has shape anisotropy in which the direction of the magnetization easy axis is orthogonal to the magnetization direction of the magnetization pinned layer.

Some magnetic sensors have means for applying a bias magnetic field to the magnetoresistive element. The bias magnetic field is used to enable the magnetoresistive element to respond linearly to a change in the strength of the target magnetic field. In a magnetic sensor that uses a spin-valve magnetoresistive element, the bias magnetic field is used also to make the free layer have a single magnetic domain and to orient the magnetization of the free layer in a certain direction, when there is no target magnetic field. Conventionally, it was not considered to meet such a demand by applying a magnetic field generator formed by stacking an antiferromagnetic layer and a ferromagnetic layer.

Next, the magnetization direction of the magnetization pinned layer and the direction of the bias magnetic field are described with reference to FIGS. 3, 5, and 6. In FIG. 3, a plurality of solid arrows drawn to overlap the resistor sections R11 to R14 and R21 to R24, respectively, represent the magnetization direction of the magnetization pinned layer in each of the resistor sections R11 to R14 and R21 to R24. In FIG. 5, the magnetization directions of the magnetization pinned layers in each of the resistor sections R11 to R14 are represented by a plurality of arrows drawn to overlap the plurality of MR elements 50A in each of the resistor sections R11 to R14. In FIG. 6, the magnetization directions of the magnetization pinned layers in each of the resistor sections R21 to R24 are represented by a plurality of arrows drawn to overlap the plurality of MR elements 50B in each of the resistor sections R21 to R24.

In the example shown in FIGS. 3 and 5, the direction of the main component of the magnetization of the magnetization pinned layer in each of the resistor sections R11 and R13 is the X direction. The direction of the main component of the magnetization of the magnetization pinned layer in each of the resistor sections R12 and R14 is the −X direction. The free layer in each of the resistor sections R11 to R14 has shape anisotropy in which the direction of the magnetization easy axis is a direction parallel to the Y direction.

In the example shown in FIGS. 3 and 6, the direction of the main component of the magnetization of the magnetization pinned layer in each of the resistor sections R21 and R23 is the Y direction. The direction of the main component of the magnetization of the magnetization pinned layer in each of the resistor sections R22 and R24 is the −Y direction. The free layer in each of the resistor sections R21 to R24 has shape anisotropy in which the direction of the magnetization easy axis is a direction parallel to the X direction.

In FIG. 3, arrows labelled with reference numerals M11, M12, M13, and M14 indicate the directions of the main components of the bias magnetic fields generated by the plurality of magnetic field generators 70A of the resistor sections R11, R12, R13, and R14, respectively. In FIG. 5, the directions of the main components of the bias magnetic fields generated by the plurality of magnetic field generators 70A are represented by a plurality of arrows drawn to overlap the plurality of magnetic field generators 70A. The direction of the main component of the bias magnetic field at the resistor sections R11 and R12 may be the Y direction. The direction of the main component of the bias magnetic field at the resistor sections R13 and R14 may be the −Y direction.

In FIG. 3, the plurality of hollow arrows drawn to overlap the resistor sections R11 to R14, respectively, represent the magnetization direction of the free layer in each of the resistor sections R11 to R14 in a case where the target magnetic field is not applied to the magnetic sensor 1. The direction of the main component of the magnetization of the free layer in each of the resistor sections R11 and R12 may be the Y direction, or may be the same as the direction of the main component of the bias magnetic field at the resistor sections R11 and R12. The direction of the main component of the magnetization of the free layer in each of the resistor sections R13 and R14 may be the −Y direction, or may be the same as the direction of the main component of the bias magnetic field at the resistor sections R13 and R14.

In FIG. 3, arrows labelled with reference numerals M21, M22, M23, and M24 indicate the directions of the main components of the bias magnetic fields generated by the plurality of magnetic field generators 70B of the resistor sections R21, R22, R23, and R24, respectively. In FIG. 6, the directions of the main components of the bias magnetic fields generated by the plurality of magnetic field generators 70B are represented by a plurality of arrows drawn to overlap the plurality of magnetic field generators 70B. The direction of the main component of the bias magnetic field at the resistor sections R21 and R22 may be the −X direction. The direction of the main component of the bias magnetic field at the resistor sections R23 and R24 may be the X direction.

In FIG. 3, the plurality of hollow arrows drawn to overlap the resistor sections R21 to R24, respectively, represent the magnetization direction of the free layer in each of the resistor sections R21 to R24 in a case where the target magnetic field is not applied to the magnetic sensor 1. The direction of the main component of the magnetization of the free layer in each of the resistor sections R21 and R22 may be the −X direction, or may be the same as the direction of the main component of the bias magnetic field at the resistor sections R21 and R22. The direction of the main component of the magnetization of the free layer in each of the resistor sections R23 and R24 may be the X direction, or may be the same as the direction of the main component of the bias magnetic field at the resistor sections R23 and R24.

Note that the magnetization direction may coincide with the direction of the main component of the magnetization mentioned above, or may deviate slightly from the direction of the main component of the magnetization. Similarly, the direction of the bias magnetic field may coincide with the direction of the main component of the bias magnetic field mentioned above, or may deviate slightly from the direction of the main component of the bias magnetic field. In the following description, the magnetization direction is assumed to coincide with the direction of the main component of the magnetization, and the direction of the bias magnetic field is assumed to coincide with the direction of the main component of the bias magnetic field.

Next, operations of the first and second detection circuits 10 and 20 are described with reference to FIG. 3. In the first detection circuit 10, the potential of the connection point between the resistor sections R11 and R12, i.e., the potential of the output port E11, and the potential of the connection point between the resistor sections R13 and R14, i.e., the potential of the output port E12, change depending on the strength of the component in a direction parallel to the X direction of the target magnetic field. The first detection circuit 10 may generate a signal corresponding to the potential of the output port E11 and a signal corresponding to the potential of the output port E12, each as a first detection signal. Alternatively, the first detection circuit 10 may generate a signal corresponding to the potential difference between the output ports E11 and E12 as a first detection signal. In this case, the first detection circuit 10 may further include a differential amplifier (difference detector) that outputs the signal corresponding to the potential difference between the output ports E11 and E12 as the first detection signal.

In the second detection circuit 20, the potential of the connection point between the resistor sections R21 and R22, i.e., the potential of the output port E21, and the potential of the connection point between the resistor sections R23 and R24, i.e., the potential of the output port E22, change depending on the strength of the component in a direction parallel to the Y direction of the target magnetic field. The second detection circuit 20 may generate a signal corresponding to the potential of the output port E21 and a signal corresponding to the potential of the output port E22, each as a second detection signal. Alternatively, the second detection circuit 20 may generate a signal corresponding to the potential difference between the output ports E21 and E22 as a second detection signal. In this case, the second detection circuit 20 may further include a differential amplifier (difference detector) that outputs the signal corresponding to the potential difference between the output ports E21 and E22 as the second detection signal.

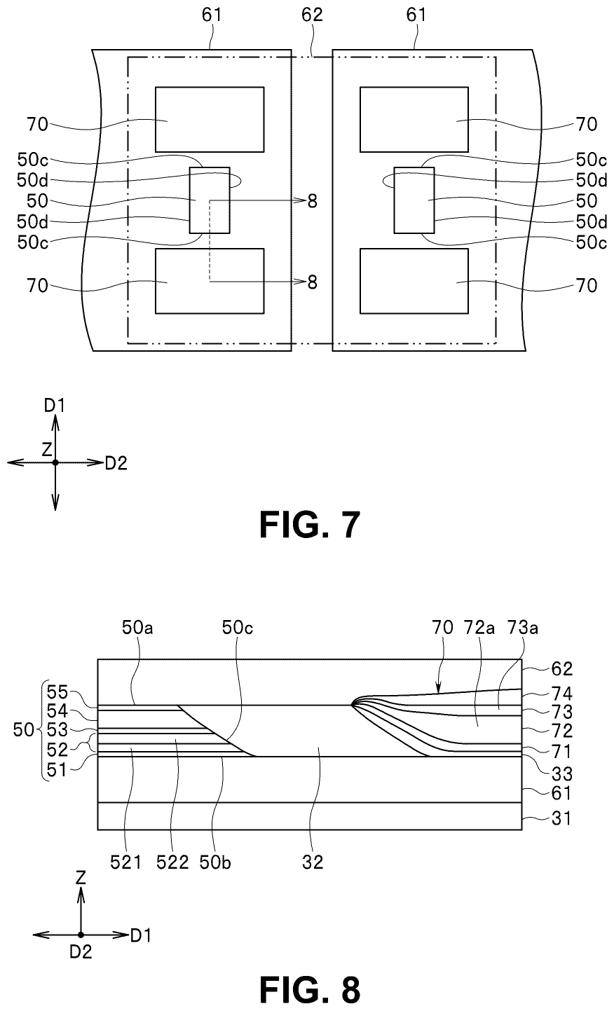

Next, configurations of the plurality of MR elements 50A, the plurality of MR elements 50B, the plurality of magnetic field generators 70A, and the plurality of magnetic field generators 70B are described in detail with reference to FIGS. 7 and 8. FIG. 7 is a plan view showing a main part of the magnetic sensor 1. FIG. 8 is a cross-sectional view showing a part of a cross section at a position indicated by an 8-8 line in FIG. 7.

Here, a first direction D1 and a second direction D2, which are each orthogonal to the Z direction and are orthogonal to each other, are defined as shown in FIGS. 7 and 8. In the first detection circuit 10, the first direction D1 is a direction parallel to the Y direction and the second direction D2 is a direction parallel to the X direction. In the second detection circuit 20, the first direction D1 is a direction parallel to the X direction and the second direction D2 is a direction parallel to the Y direction.

Hereinafter, any MR element of the plurality of MR elements 50A and the plurality of MR elements 50B will be denoted using reference numeral 50, and any magnetic field generator of the plurality of magnetic field generators 70A and the plurality of magnetic field generators 70B will be denoted using reference numeral 70. The magnetic sensor 1 includes at least one MR element 50. In the example embodiment in particular, the magnetic sensor 1 includes a plurality of MR elements 50 as the at least one MR element 50.

Here, configurations of the MR element 50 and a magnetic field generator 70 are described with a focus on one MR element 50. The MR element 50 includes a plurality of magnetic films. The stacking direction of the plurality of magnetic films is a direction parallel to the Z direction. The plurality of magnetic films include a magnetization pinned layer 52 and a free layer 54. Each of the plurality of MR elements 50 further includes a gap layer 53, a buffer layer 51, and a cap layer 55. As shown in FIG. 8, the buffer layer 51, the magnetization pinned layer 52, the gap layer 53, the free layer 54, and the cap layer 55 are stacked in this order in the Z direction. Each of the buffer layer 51 and the cap layer 55 is formed of a nonmagnetic metallic material such as, for example, Ru, Ta, Cu, or Cr. The free layer 54 is formed of a soft magnetic material such as, for example, CoFe, CoFeB, NiFe, or CoNiFe.

The magnetization pinned layer 52 may include an antiferromagnetic layer 521 disposed on the buffer layer 51 and a ferromagnetic layer 522 disposed on the antiferromagnetic layer 521. The antiferromagnetic layer 521 is in contact with the bottom surface of the ferromagnetic layer 522 to generate exchange coupling with the ferromagnetic layer 522 to fix the magnetization direction of the ferromagnetic layer 522. The magnetization direction of the magnetization pinned layer 52 is the same as the magnetization direction of the ferromagnetic layer 522.

The antiferromagnetic layer 521 is formed of an antiferromagnetic material such as, for example, IrMn or PtMn. The antiferromagnetic layer 73a of the antiferromagnetic portion 73 of the magnetic field generator 70 and the antiferromagnetic layer 521 may contain at least one same element. The ferromagnetic layer 522 is formed of a ferromagnetic material containing one or more elements selected from the group consisting of Co, Fe, and Ni.

The MR element 50 includes a top surface 50a located at the end in the Z direction, a bottom surface 50b located at the end in the −Z direction, two side surfaces 50c located at both ends in the first direction D1, and two side surfaces 50d located at both ends in the second direction D2. The bottom surface 50b of the MR element 50 is in contact with the lower electrode 61. Each of the two side surfaces 50c and the two side surfaces 50d is inclined with respect to the stacking direction (a direction parallel to the Z direction) of the plurality of magnetic films.

The magnetic sensor 1 further includes at least one magnetic field generator 70 configured to generate a bias magnetic field to be applied to the MR element 50. In the example embodiment in particular, the magnetic sensor 1 includes two magnetic field generators 70 disposed with the MR element 50 interposed therebetween. The MR element 50 is disposed between two magnetic field generators 70 in the first direction D1.

In the example embodiment, each of the two magnetic field generators 70 is located at a predetermined distance from the MR element 50. Each of the two magnetic field generators 70 does not overlap the MR element 50 when viewed from the Z direction.

Each of the two magnetic field generators 70 includes a ferromagnetic portion 72 made of a ferromagnetic material and an antiferromagnetic portion 73 made of an antiferromagnetic material. In the example embodiment in particular, the antiferromagnetic portion 73 is disposed on the ferromagnetic portion 72.

At least a part of each of the two magnetic field generators 70 overlaps the MR element 50 when viewed from the first direction D1. In the example embodiment, the ferromagnetic portion 72 includes a ferromagnetic layer 72a made of a ferromagnetic material. The ferromagnetic layer 72a is disposed to overlap the MR element 50 when viewed from the first direction D1. The ferromagnetic layer 72a may be disposed to overlap the entirety of the free layer 54 when viewed from the first direction D1.

The ferromagnetic layer 72a is formed of a ferromagnetic material containing one or more elements selected from the group consisting of Co, Fe, and Ni. Examples of such a ferromagnetic material include CoFe, CoFeB, and CoNiFe.

Note that the ferromagnetic portion 72 may include, instead of the ferromagnetic layer 72a, a stack including a plurality of stacked ferromagnetic layers, in which two adjacent layers are made of ferromagnetic materials different from each other. Examples of such a stack include a stack of a Co layer, a CoFe layer, and a Co layer, and a stack of a Co₇₀Fe₃₀ layer, a Co₃₀Fe₇₀ layer, and a Co₇₀Fe₃₀ layer. Note that Co₇₀Fe₃₀ represents an alloy containing 70 atomic percent Co and 30 atomic percent Fe, and Co₃₀Fe₇₀ represents an alloy containing 30 atomic percent Co and 70 atomic percent Fe.

The antiferromagnetic portion 73 includes an antiferromagnetic layer 73a made of an antiferromagnetic material. The antiferromagnetic layer 73a is disposed on and in contact with the ferromagnetic layer 72a. The antiferromagnetic layer 73a is formed of an antiferromagnetic material such as, for example, IrMn or PtMn.

The ferromagnetic layer 72a has an overall magnetization. The net magnetization of the ferromagnetic layer 72a is a volume average of the vector sum of magnetic moments for each unit of atoms, crystal lattices, etc. in the overall ferromagnetic layer 72a. Hereinafter, the net magnetization of the ferromagnetic layer 72a is simply referred to as magnetization of the ferromagnetic layer 72a. The antiferromagnetic layer 73a is in contact with the top surface of the ferromagnetic layer 72a to be exchange-coupled with the ferromagnetic layer 72a. This defines the magnetization direction of the ferromagnetic layer 72a.

In the example embodiment, substantially the entirety of the ferromagnetic portion 72 is constituted by the ferromagnetic layer 72a, and substantially the entirety of the antiferromagnetic portion 73 is constituted by the antiferromagnetic layer 73a. The antiferromagnetic layer 73a is exchange-coupled with the ferromagnetic layer 72a, and thereby the antiferromagnetic portion 73 is exchange-coupled with the ferromagnetic portion 72. This defines the magnetization direction of the ferromagnetic portion 72. The magnetization direction of the ferromagnetic portion 72 coincides with the magnetization direction of the ferromagnetic layer 72a. The ferromagnetic portion 72 and the antiferromagnetic portion 73 generate a bias magnetic field based on the magnetization of the ferromagnetic portion 72. The magnetic field generator 70 thus constituted is highly resistant to disturbance magnetic fields.

The two magnetic field generators 70 cooperate to apply a bias magnetic field to the MR element 50. The magnetization direction of the ferromagnetic portion 72 of one of the two magnetic field generators 70 may be the same as the magnetization direction of the ferromagnetic portion 72 of the other of the two magnetic field generators 70. In this case, the direction of the bias magnetic field generated by one of the two magnetic field generators 70 becomes the same as the direction of the bias magnetic field generated by the other of the two magnetic field generators 70.

Each of the two magnetic field generators 70 further includes a buffer layer 71 disposed on the bottom surface side (−Z direction side) of the ferromagnetic layer 72a and a cap layer 74 disposed on the antiferromagnetic layer 73a. Each of the buffer layer 71 and the cap layer 74 is formed of a nonmagnetic metallic material such as, for example, Ru, Ta, Cu, or Cr.

The magnetic sensor 1 further includes an insulating layer 32 made of an insulating material such as Al₂O₃ or SiO₂ and disposed around the MR element 50 and the two magnetic field generators 70. The insulating layer 32 is interposed between the MR element 50 and the two magnetic field generators 70.

The magnetic sensor 1 further includes an insulating layer 31 made of an insulating material and interposed between the substrate 30 (see FIGS. 4 through 6) and the lower electrode 61, and an insulating layer 33 made of an insulating material and interposed between the insulating layer 32 and the two magnetic field generators 70. The insulating layer 33 is further interposed between the two magnetic field generators 70 and the lower electrode 61. The insulating layers 31 and 33 are formed of an insulating material such as, for example, Al₂O₃ or SiO₂.

The upper electrode 62 is disposed on the MR element 50, the two magnetic field generators 70, and the insulating layer 32. The top surface 50a of the MR element 50, and the top surface of each of the two magnetic field generators 70, i.e., the top surface of the cap layer 74, are in contact with the upper electrode 62. The magnetic sensor 1 further includes an insulating layer (not shown) formed of an insulating material and disposed on the upper electrode 62.

Heretofore, the configurations of the MR element 50 and the magnetic field generator 70 have been described with a focus on one MR element 50. In the example embodiment, the magnetic sensor 1 includes the plurality of MR elements 50. Therefore, the magnetic sensor 1 includes a plurality of magnetic field generators 70.

A plurality of arrows drawn to overlap the plurality of magnetic field generators 70A in FIG. 5 and a plurality of arrows drawn to overlap the plurality of magnetic field generators 70B in FIG. 6 substantially indicate the magnetization direction of the ferromagnetic portion 72 of the plurality of magnetic field generators 70. Here, the magnetic field generator 70 of the plurality of magnetic field generators 70 configured to apply a bias magnetic field to each of the plurality of MR elements 50 of any resistor section is referred to as the magnetic field generator 70 corresponding to the any resistor section. In the example shown in FIG. 5, the magnetization direction of the ferromagnetic portion 72 of the plurality of magnetic field generators 70A corresponding to the resistor sections R11 and R12 is the Y direction. The magnetization direction of the ferromagnetic portion 72 of the plurality of magnetic field generators 70A corresponding to the resistor sections R13 and R14 is the −Y direction.

In the example shown in FIG. 6, the magnetization direction of the ferromagnetic portion 72 of the plurality of magnetic field generators 70B corresponding to the resistor sections R21 and R22 is the −X direction. The magnetization direction of the ferromagnetic portion 72 of the plurality of magnetic field generators 70B corresponding to the resistor sections R23 and R24 is the X direction.

FIGS. 5 and 6 show a first example of the magnetization direction of the ferromagnetic portion 72 of the magnetic field generator 70. Other plurality of examples of the magnetization direction of the ferromagnetic portion 72 of the magnetic field generator 70 are described later.

Next, a manufacturing method of the magnetic sensor 1 according to the example embodiment is described. The manufacturing method of the magnetic sensor 1 includes a process of forming at least one MR element 50 and a process of forming at least one magnetic field generator 70. In the example embodiment in particular, the process of forming the at least one MR element 50 is a process of forming a plurality of MR elements 50, and the process of forming the at least one magnetic field generator 70 is a process of forming the plurality of magnetic field generators 70.

Initially, the process of forming the plurality of MR elements 50 is described. In the process of forming the plurality of MR elements 50, a plurality of initial MR elements that later become the plurality of MR elements 50 may first be formed. Each of the plurality of initial MR elements includes an initial magnetization pinned layer that later becomes a magnetization pinned layer 52, a buffer layer 51, a gap layer 53, a free layer 54, and a cap layer 55. The initial magnetization pinned layer includes the antiferromagnetic layer 521 and the ferromagnetic layer 522.

Next, the magnetization direction of the initial magnetization pinned layer may be fixed in a predetermined direction by using laser light and an external magnetic field that contains a component in the predetermined direction. This process is hereinafter referred to as a process of fixing the magnetization direction of the initial magnetization pinned layer or a process of fixing the magnetization direction of the magnetization pinned layer 52. The predetermined direction may coincide with the magnetization direction of the magnetization pinned layer 52. For example, in the plurality of initial MR elements that later become the plurality of MR elements 50A constituting the resistor sections R11 and R13 of the first detection circuit 10, the plurality of initial MR elements are irradiated with laser light while applying an external magnetic field in the X direction thereto. The irradiation of the laser light is performed so that the temperature of the plurality of initial MR elements irradiated with the laser light becomes equal to or higher than a blocking temperature of the antiferromagnetic layer 521 of the initial magnetization pinned layer. The temperature of the plurality of initial MR elements can be adjusted, for example, by the strength and pulse width of the laser light. After the irradiation of the laser light, when the temperature of the plurality of initial MR elements becomes lower than the blocking temperature, the magnetization direction of the initial magnetization pinned layer is fixed in the X direction. This causes the initial magnetization pinned layers to become the magnetization pinned layer 52.

In the plurality of initial MR elements that later become the plurality of MR elements 50A constituting the resistor sections R12 and R14 of the first detection circuit 10, the magnetization direction of the initial magnetization pinned layer of each of the plurality of initial MR elements can be fixed in the −X direction by using an external magnetic field in the −X direction. The magnetization direction of the magnetization pinned layer 52 of each of a plurality of MR elements 50B constituting each of the resistor sections R21 to R24 of the second detection circuit 20 is also fixed by the same method as with the magnetization pinned layer 52 of each of the plurality of MR elements 50A.

The MR element 50 is completed by patterning the stacked film by etching so that two side surfaces 50c and two side surfaces 50d are formed on the stacked film after fixing the magnetization direction of the magnetization pinned layer 52. Note that the process of fixing the magnetization direction of the initial magnetization pinned layer may be performed after forming the two side surfaces 50c and the two side surfaces 50d on the stacked film.

Next, a process of forming the plurality of magnetic field generators 70 is described. Initially, an overview of a process of forming two magnetic field generators 70 is described with a focus on one MR element 50. First, a photoresist mask is formed on the MR element 50 and the insulating layer 32. Next, the insulating layer 32 is etched. Next, while leaving the photoresist mask in place, the insulating layer 33 and two initial magnetic field generators 70P that later become the two magnetic field generators 70 are formed in order. Each of the two initial magnetic field generators 70P includes an initial ferromagnetic portion that later becomes the ferromagnetic portion 72, a buffer layer 71, the antiferromagnetic portion 73, and the cap layer 74. The buffer layer 71, the initial ferromagnetic portion, the antiferromagnetic portion 73, and the cap layer 74 are stacked in this order. Next, the photoresist mask is removed.

Next, the magnetization direction of the initial ferromagnetic portion is fixed in a predetermined direction by using laser light and an external magnetic field including a component in the predetermined direction. This process is hereinafter referred to as a process of fixing the magnetization direction of the initial ferromagnetic portion or a process of fixing the magnetization direction of the ferromagnetic portion 72. The predetermined direction may coincide with the magnetization direction of the ferromagnetic portion 72. The method of fixing the magnetization direction of the initial ferromagnetic portion is the same as the method of fixing the magnetization direction of the initial magnetization pinned layer. That is, each of the two initial magnetic field generators 70P is irradiated with laser light while applying an external magnetic field thereto. The irradiation of the laser light is performed so that the temperature of the two initial magnetic field generators 70P irradiated with the laser light becomes equal to or higher than a blocking temperature of the antiferromagnetic portion 73. The temperature of the two initial magnetic field generators 70P can be adjusted, for example, by the strength and pulse width of the laser light. After the irradiation of the laser light, when the temperature of the two initial magnetic field generators 70P becomes lower than the blocking temperature, the magnetization direction of the initial ferromagnetic portion is fixed in the above-described predetermined direction. This causes the initial ferromagnetic layer to become a ferromagnetic portion 72 and the two initial magnetic field generators 70P to become the two magnetic field generators 70.

Note that the strength of the laser light used to fix the magnetization direction of the initial ferromagnetic portion may be smaller than the strength of the laser light used to fix the magnetization direction of the initial magnetization pinned layer. The intensity of the laser light used to fix the magnetization direction of the initial ferromagnetic portion may be an intensity such that the change in magneto resistance ratio, which is the ratio of the magnetoresistive change to the resistance of the MR element 50, is restrained.

If each of the two magnetic field generators 70 has a plurality of side surfaces formed by etching, the process of fixing the magnetization direction of the initial ferromagnetic portion may be performed before or after forming at least one of the plurality of side surfaces.

Note that in the example embodiment, the ferromagnetic portion 72 is substantially the ferromagnetic layer 72a. Therefore, the initial ferromagnetic portion is substantially an initial ferromagnetic layer that later becomes the ferromagnetic layer 72a. The process of forming the plurality of magnetic field generators 70 can be described by replacing the ferromagnetic portion 72 and the initial ferromagnetic portion with the ferromagnetic layer 72a and the initial ferromagnetic layer, respectively.

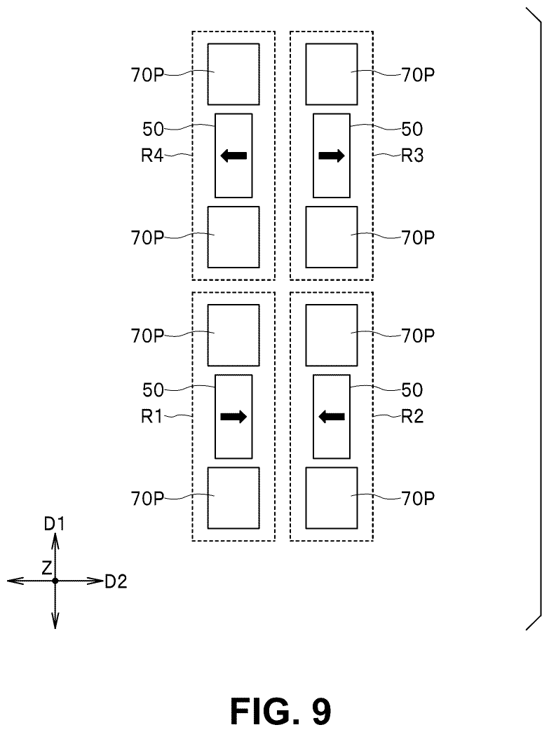

Next, the process of fixing the magnetization direction of the initial ferromagnetic layer is described in further detail with reference to FIGS. 9 through 13. In FIGS. 9 through 13, four resistor sections R11 to R14 of the first detection circuit 10 or four resistor sections R21 to R24 of the second detection circuit 20 are schematically shown. In FIGS. 9 through 13, reference numeral R1 indicates a resistor section corresponding to the resistor section R11 or the resistor section R21. Reference numeral R2 indicates a resistor section corresponding to the resistor section R12 or the resistor section R22. Reference numeral R3 indicates a resistor section corresponding to the resistor section R13 or the resistor section R23. Reference numeral R4 indicates a resistor section corresponding to the resistor section R14 or the resistor section R24.

In FIGS. 9 through 13, one MR element 50 is shown, representing the plurality of MR elements 50 in each of the resistor sections R1 to R4. A plurality of initial magnetic field generators 70P or the plurality of magnetic field generators 70 disposed with the one MR element 50 of each of the resistor sections R1 to R4 interposed therebetween are shown, representing the plurality of initial magnetic field generators 70P or the plurality of magnetic field generators 70. FIGS. 9 through 13 also show a first direction D1 and a second direction D2. Note that the same manner of representation as in FIGS. 9 through 13 is also used in the similar plurality of figures as FIGS. 9 through 13, which will be used in the subsequent description.

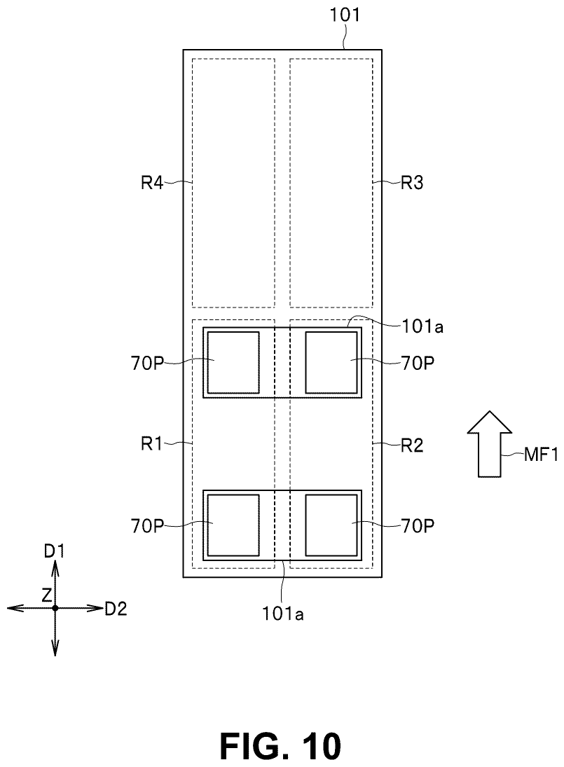

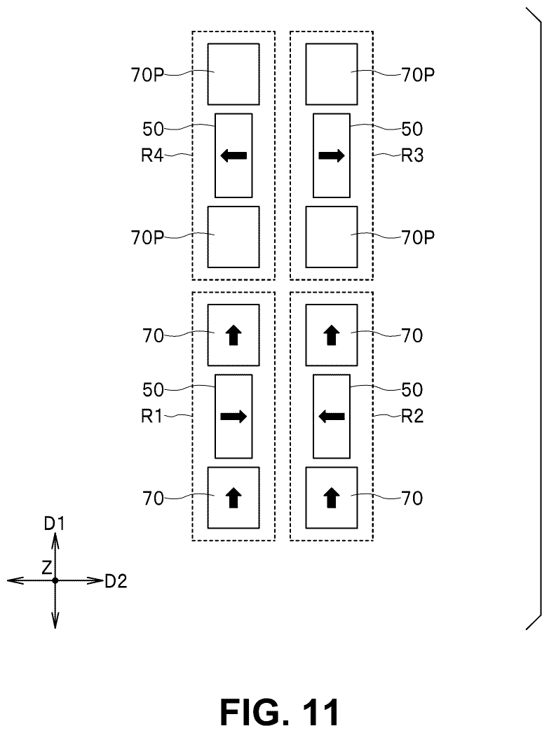

FIG. 9 shows the resistor sections R1 to R4 after the plurality of initial magnetic field generators 70P are formed. FIG. 10 shows the next process. In this process, the plurality of initial magnetic field generators 70P corresponding to the resistor sections R1 and R2 are selectively irradiated with laser light, while applying a magnetic field component MF1 in one direction parallel to the first direction D1 (direction from bottom to top in FIG. 10) to the magnetic sensor 1. After the irradiation of the laser light, the magnetization direction of the initial ferromagnetic layer of each of the irradiated plurality of initial magnetic field generators 70P is fixed in the same direction as the magnetic field component MF1. This causes the plurality of initial magnetic field generators 70P irradiated with the laser light to become the plurality of magnetic field generators 70, as shown in FIG. 11.

A plurality of initial magnetic field generators 70P may be selectively irradiated with the laser light by using a mask 101, for example. The mask 101 has a plurality of openings 101a that expose some or all of the plurality of initial magnetic field generators 70P corresponding to the resistor sections R1 and R2. The plurality of MR elements 50 of the resistor sections R1 to R4 and the plurality of initial magnetic field generators 70P corresponding to the resistor sections R3 and R4 are covered by the mask 101. The irradiation of the laser light is performed through the plurality of openings 101a to some or all of the plurality of initial magnetic field generators 70P. If some of the plurality of initial magnetic field generators 70P are irradiated with the laser light, all of the initial magnetic field generators 70P corresponding to the resistor sections R1 and R2 are irradiated with the laser light while moving the magnetic sensor 1 by using a stage, for example.

Note that although the plurality of MR elements 50 are not irradiated with the laser light, the temperature of the plurality of MR elements 50 can also rise during the irradiation of the laser light. However, the temperature of the plurality of MR elements 50 will not become higher than the blocking temperature of the antiferromagnetic layer 521.

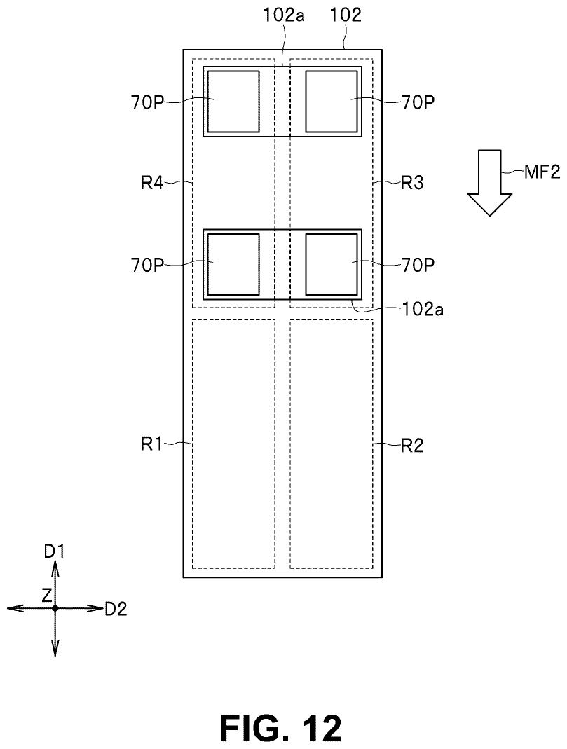

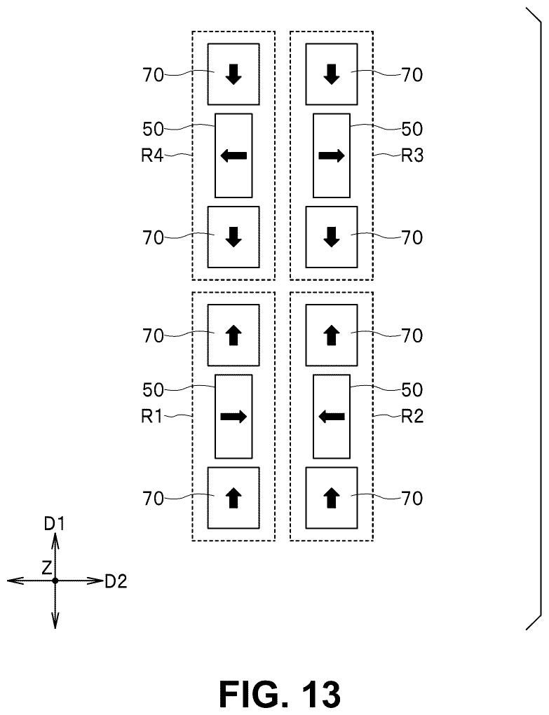

FIG. 12 shows the next process. In this process, the plurality of initial magnetic field generators 70P corresponding to the resistor sections R3 and R4 are selectively irradiated with the laser light while applying a magnetic field component MF2 in one other direction parallel to the first direction D1 (direction from top to bottom in FIG. 12) to the magnetic sensor 1. After the irradiation of the laser light, the magnetization direction of the initial ferromagnetic layer of each of the irradiated plurality of initial magnetic field generators 70P is fixed in the same direction as the magnetic field component MF2. This causes the plurality of initial magnetic field generators 70P irradiated with the laser light to become the plurality of magnetic field generators 70, as shown in FIG. 13.

As in the process shown in FIG. 10, the plurality of initial magnetic field generators 70P may be selectively irradiated with the laser light by using a mask 102, for example. The mask 102 has a plurality of openings 102a that expose some or all of the plurality of initial magnetic field generators 70P corresponding to the resistor sections R3 and R4. The plurality of MR elements 50 of the resistor sections R1 to R4 and the plurality of magnetic field generators 70 corresponding to the resistor sections R1 and R2 are covered by the mask 102. The irradiation of the laser light is performed through the plurality of openings 102a to some or all of the plurality of initial magnetic field generators 70P. If some of the plurality of initial magnetic field generators 70P are irradiated with the laser light, all of the initial magnetic field generators 70P corresponding to the plurality of MR elements 50 of the resistor sections R3 and R4 are irradiated with the laser light while moving the magnetic sensor 1 using a stage, for example.

Note that although the resistor sections R1 and R2 are not irradiated with the laser light, the temperature of the plurality of magnetic field generators 70 corresponding to the resistor sections R1 and R2 can also rise during the irradiation of the laser light. However, the temperature of the plurality of magnetic field generators 70 corresponding to the resistor sections R1 and R2 does not become higher than the blocking temperature of the antiferromagnetic portion 73.

The manufacturing method of the magnetic sensor 1 may further include a process of performing an annealing process that heats, at a predetermined temperature, a stack including the plurality of MR elements 50 in each of which the magnetization direction of the magnetization pinned layer 52 is fixed and the plurality of magnetic field generators 70 in each of which the magnetization direction of the ferromagnetic portion 72 is fixed. The annealing process may be performed using an electric furnace, for example. Performing the annealing process enables to stabilize the magnetization direction of the magnetization pinned layer 52 and the magnetization direction of the ferromagnetic portion 72. As a result, it is enabled to restrain the characteristic fluctuation of the magnetic sensor 1 after the magnetic sensor 1 is completed.

Next, an effect of the magnetic sensor 1 according to the example embodiment is described. As shown in FIG. 5, in the example embodiment, some of the plurality of MR elements 50A of the resistor section R11 and some of the plurality of MR elements 50A of the resistor section R14 are adjacent to each other without another MR element 50A capable of detecting the magnetoresistive effect interposed therebetween. Here, a set of the plurality of magnetic field generators 70A that apply a bias magnetic field to some of the plurality of MR elements 50A of the resistor section R11 and some of the plurality of MR elements 50A of the resistor section R11 is referred to as a first set. A set of the plurality of magnetic field generators 70A that apply a bias magnetic field to some of the plurality of MR elements 50A of the resistor section R14 and some of the plurality of MR elements 50A of the resistor section R14 is referred to as a second set. No other set of another MR element 50 capable of detecting the magnetoresistive effect and another magnetic field generator 70 is interposed between the first set and the second set.

Note that the MR element 50 to which any electrode can be connected to detect a resistance value corresponds to the other MR element 50 capable of detecting the magnetoresistive effect. On the other hand, the MR elements that do not correspond to the MR elements 50 capable of detecting the magnetoresistive effect include the following first through third MR elements, for example. The first MR element is an MR element to which any electrode is not connected and cannot detect the resistance value of the MR element. The second MR element is a GMR element of CIP (Current In Plane) type in which the current flows in a direction approximately parallel to the plane of each layer constituting the MR element, and in which a thick conductive film is formed on the GMR element. The third MR element is an MR element whose resistance value does not change even if the direction or strength of the applied magnetic field changes because the configuration of the MR element is incomplete. Examples of such an MR element include, for example, a TMR or GMR element in which the magnetization direction of the magnetization pinned layer is not fixed.

For the magnetic sensor 1, there may be a demand that when there is no target magnetic field, the magnetization direction of the free layer 54 in the first set and the magnetization direction of the free layer 54 in the second set be different from each other. In contrast, in the example embodiment, the magnetization direction of the ferromagnetic portion 72 of the magnetic field generator 70A in the first set and the magnetization direction of the ferromagnetic portion 72 of the magnetic field generator 70A in the second set are made different from each other. In the example embodiment in particular, the magnetization direction of the ferromagnetic portion 72 of the magnetic field generator 70A in the first set and the magnetization direction of the ferromagnetic portion 72 of the magnetic field generator 70A in the second set may be opposite each other. Therefore, the direction of the main component of the bias magnetic field generated by the magnetic field generator 70A in the first set and the direction of the main component of the bias magnetic field generated by the magnetic field generator 70A in the second set are also opposite each other. According to the example embodiment, this enables that when there is no target magnetic field, the magnetization direction of the free layer 54 in the first set and the magnetization direction of the free layer 54 in the second set is made different from each other.

Note that as shown in FIG. 5, in the example embodiment, some of the plurality of MR elements 50A of the resistor section R12 and some of the plurality of MR elements 50A of the resistor section R13 are adjacent to each other without another MR element 50A capable of detecting the magnetoresistive effect interposed therebetween. Here, a set of the plurality of magnetic field generators 70A that apply a bias magnetic field to some of the plurality of MR elements 50A of the resistor section R12 and some of the plurality of MR elements 50A of the resistor section R12 is referred to as a third set. A set of the plurality of magnetic field generators 70A that apply a bias magnetic field to some of the plurality of MR elements 50A of the resistor section R13 and some of the plurality of MR elements 50A of the resistor section R13 is referred to as a fourth set. No other set of another MR element 50 capable of detecting the magnetoresistive effect and another magnetic field generator 70 is interposed between the third set and the fourth set. The third set may be adjacent to one of the first set and the second set at a predetermined distance. The fourth set may be adjacent to the other of the first set and the second set at a predetermined distance.

The above description of the plurality of magnetic field generators 70A corresponding to the resistor sections R11 and R14 also applies to the plurality of magnetic field generators 70A corresponding to the resistor sections R12 and R13. The above description of the resistor sections R11 to R14 also applies to the resistor sections R21 to R24.

Although not shown, one or two of the resistor sections R11 to R14 (hereinafter referred to as a first resistor section) is adjacent to one or two of the resistor sections R21 to R24 (hereinafter referred to as a second resistor section). In the magnetic sensor 1, there may be a demand that when there is no target magnetic field, the magnetization direction of the free layer 54 of each of the plurality of MR elements 50A of the first resistor section and the magnetization direction of the free layer 54 of each of the plurality of MR elements 50B of the second resistor section be different from each other.

In the example embodiment, the magnetization direction of the ferromagnetic portion 72 of the plurality of magnetic field generators 70A corresponding to the first resistor section and the magnetization direction of the ferromagnetic portion 72 of the plurality of magnetic field generators 70B corresponding to the second resistor section are made different from each other. In the example embodiment in particular, the magnetization direction of the ferromagnetic portion 72 of the plurality of magnetic field generators 70A corresponding to the first resistor section and the magnetization direction of the ferromagnetic portion 72 of the plurality of magnetic field generators 70B corresponding to the second resistor section may be orthogonal to each other. Therefore, the direction of the main component of the bias magnetic field generated by the plurality of magnetic field generators 70A corresponding to the first resistor section and the direction of the main component of the bias magnetic field generated by the plurality of magnetic field generators 70B corresponding to the second resistor section are also orthogonal to each other. According to the example embodiment, this enables that when there is no target magnetic field, the magnetization direction of the free layer 54 of each of the plurality of MR elements 50A of the first resistor section and the magnetization direction of the free layer 54 of each of the plurality of MR elements 50B of the second resistor section is made different from each other.

Next, second through twelfth examples of the arrangement of the resistor sections R11 to R14 and R21 to R24 in the substrate 30 and the magnetization direction of the ferromagnetic portion 72 of the magnetic field generator 70 are described.

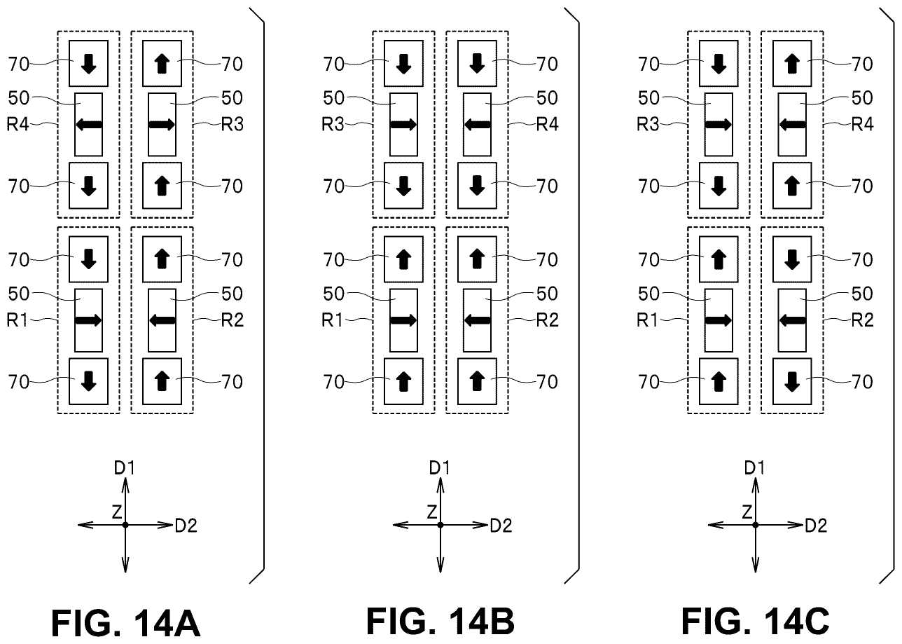

FIG. 14A shows a second example. In FIG. 14A, the resistor sections R11 to R14 and R21 to R24 are represented using the resistor sections R1 to R4 shown in FIGS. 9 through 13. In the second example, the arrangement of the resistor sections R1 to R4 is the same as the first example of the arrangement of the resistor sections R11 to R14 shown in FIG. 5 and as the first example of the arrangement of the resistor sections R21 to R24 shown in FIG. 6. In other words, FIG. 14A shows that the arrangement of the resistor sections R1 to R4 is the same as the arrangement of the resistor sections R11 to R14 shown in FIG. 5 and as the arrangement of resistor sections R21 to R24 shown in FIG. 6.

In FIG. 14A, a plurality of arrows drawn to overlap the resistor sections R1 to R4, respectively, represent the magnetization direction of the magnetization pinned layer 52 in each of the resistor sections R1 to R4. FIG. 14A shows that the magnetization direction of the magnetization pinned layer 52 in each of the resistor sections R1 to R4 is the same as the magnetization direction of the magnetization pinned layer in each of the resistor sections R11 to R14 shown in FIG. 5 and as the magnetization direction of the magnetization pinned layer in each of the resistor sections R21 to R24 shown in FIG. 6. In other words, as previously mentioned, the magnetization direction of the magnetization pinned layer 52 in each of the resistor sections R11 and R13 is the X direction, and the direction of the main component of magnetization of the magnetization pinned layers in each of the resistor sections R21 and R23 is the Y direction. In FIG. 14A, the magnetization direction of the magnetization pinned layer 52 in each of the resistor sections R1 and R3 corresponding to the resistor sections R11 and R13 or the resistor sections R21 and R23 is represented by an arrow in one direction parallel to the second direction D2 (direction from the resistor section R1 to the resistor section R2 in FIG. 14A).

As previously mentioned, the magnetization direction of the magnetization pinned layer in each of the resistor sections R12 and R14 is the −X direction, and the magnetization direction of the magnetization pinned layer in each of the resistor sections R22 and R24 is the −Y direction. In FIG. 14A, the magnetization direction of the magnetization pinned layer 52 in each of the resistor sections R2 and R4 corresponding to the resistor sections R12 and R14 or the resistor sections R22 and R24 is represented by an arrow in one other direction parallel to the second direction D2 (direction from the resistor section R2 to the resistor section R1 in FIG. 14A).

In FIG. 14A, a plurality of arrows drawn to overlap the plurality of magnetic field generators 70, respectively, each represent the magnetization direction of the ferromagnetic portion 72 of each of the plurality of magnetic field generators 70. In the second example, the magnetization direction of the ferromagnetic portion 72 of each of the plurality of magnetic field generators 70 corresponding to the resistor sections R1 and R4 is one direction parallel to the first direction D1 (direction from the resistor section R4 to the resistor section R1 in FIG. 14A). That is, the magnetization direction of the ferromagnetic portion 72 of each of the plurality of magnetic field generators 70A corresponding to the resistor sections R11 and R14 is the −Y direction, and the magnetization direction of the ferromagnetic portion 72 of each of the plurality of magnetic field generators 70B corresponding to the resistor sections R21 and R24 is the X direction.

In the second example, the magnetization direction of the ferromagnetic portion 72 of each of the plurality of magnetic field generators 70 corresponding to the resistor sections R2 and R3 is one other direction parallel to the first direction D1 (direction from the resistor section R2 to the resistor section R3 in FIG. 14A). That is, the magnetization direction of the ferromagnetic portion 72 of each of the plurality of magnetic field generators 70A corresponding to the resistor sections R12 and R13 is the Y direction, and the magnetization direction of the ferromagnetic portion 72 of each of the plurality of magnetic field generators 70B corresponding to the resistor sections R22 and R23 is the −X direction.

As described above, in the second example, the arrangement of the resistor sections R1 to R4 is the same as that in the first example shown in FIGS. 5 and 6, but the magnetization direction of the ferromagnetic portion 72 of the magnetic field generator 70 is different from that in the first example.

Note that in a similar plurality of figures as FIG. 14A used in the subsequent description, the same manner of representation as in FIG. 14A is also used for the arrangement of the resistor sections R1 to R4 (resistor sections R11 to R14 and R21 to R24) and for the magnetization direction of the ferromagnetic portion 72 of the magnetic field generator 70. In the subsequent description, the descriptions of the correspondence between the resistor sections R1 to R4 and the resistor sections R11 to R14 and R21 to R24 and of the correspondence between the first and second directions D1 and D2 and the X and Y directions will be omitted.

FIG. 14B shows a third example. In the third example, the magnetization direction of the ferromagnetic portion 72 of the magnetic field generator 70 is the same as in the first example shown in FIGS. 5 and 6, but the arrangement of the resistor sections R3 and R4 is different from that in the first example. That is, in the third example, the resistor sections R3 and R4 are disposed forward of the resistor sections R1 and R2, respectively, in one direction parallel to the first direction D1.

FIG. 14C shows a fourth example. In the fourth example, the arrangement of the resistor sections R1 to R4 and the magnetization direction of the ferromagnetic portion 72 of each of the plurality of magnetic field generators 70 corresponding to the resistor sections R1 and R3 are the same as those in the third example shown in FIG. 14B, but the magnetization direction of the ferromagnetic portion 72 of each of the plurality of magnetic field generators 70 corresponding to resistor sections R2 and R4 is different from that in the third example. That is, in the fourth example, the magnetization direction of the ferromagnetic portion 72 of each of the plurality of magnetic field generators 70 corresponding to the resistor section R2 is the same as the magnetization direction of the ferromagnetic portion 72 of each of the plurality of magnetic field generators 70 corresponding to the resistor section R3, and is the opposite to that in the third example. The magnetization direction of the ferromagnetic portion 72 of each of the plurality of magnetic field generators 70 corresponding to the resistor section R4 is the same as the magnetization direction of the ferromagnetic portion 72 of each of the plurality of magnetic field generators 70 corresponding to the resistor section R1, and is the opposite direction to that in the third example.

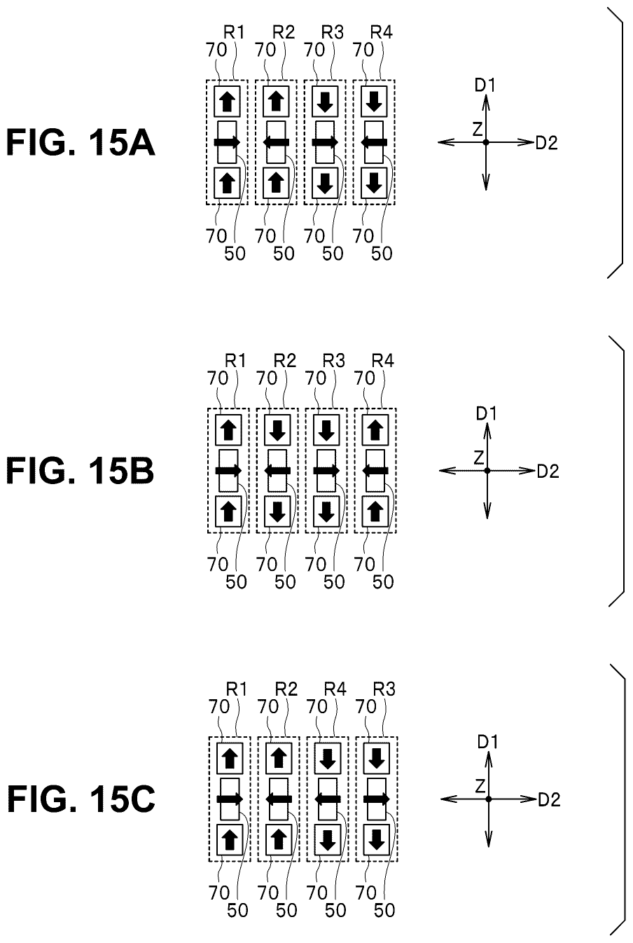

FIG. 15A shows a fifth example. In the fifth example, the magnetization direction of the ferromagnetic portion 72 of the magnetic field generator 70 is the same as that in the first example shown in FIGS. 5 and 6, but the arrangement of the resistor sections R1 to R4 is different from that in the first example. That is, in the fifth example, the resistor sections R1 to R4 are arranged in this order in one direction parallel to the second direction D2.

FIG. 15B shows a sixth example. In the sixth example, the arrangement of the resistor sections R1 to R4 is the same as that in the fifth example shown in FIG. 15A, and the magnetization direction of the ferromagnetic portion 72 of the magnetic field generator 70 is the same as that in the fourth example shown in FIG. 14C.

FIG. 15C shows a seventh example. In the seventh example, the arrangement of the resistor sections R1 and R2 and the magnetization direction of the ferromagnetic portion 72 of the magnetic field generator 70 are the same as those in the fifth example shown in FIG. 15A, but the arrangement of the resistor sections R3 and R4 is different from that in the fifth example. That is, in the seventh example, the resistor section R4 is located at a position where the resistor section R2 is interposed between the resistor section R4 and the resistor section R1 in the second direction D2. The resistor section R3 is located at a position where the resistor section R4 is interposed between the resistor section R3 and the resistor section R2 in the second direction D2.

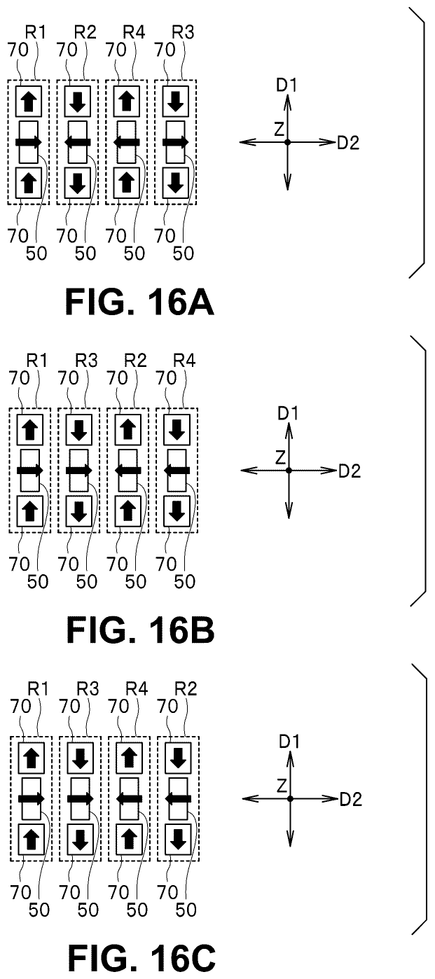

FIG. 16A shows an eighth example. In the eighth example, the arrangement of the resistor sections R1 to R4 is the same as that in the seventh example shown in FIG. 15C, and the magnetization direction of the ferromagnetic portion 72 of the magnetic field generator 70 is the same as that in the sixth example shown in FIG. 15B.

FIG. 16B shows a ninth example. In the ninth example, the arrangement of the resistor sections R1 and R4 and the magnetization direction of the ferromagnetic portion 72 of the magnetic field generator 70 are the same as those in the fifth example shown in FIG. 15A, but the arrangement of the resistor sections R2 and R3 is different from that in the fifth example. That is, in the ninth example, the resistor sections R2 and R3 are disposed between the resistor sections R1 and R4. The resistor section R2 is located at a position closer to the resistor section R4 than the resistor section R1. The resistor section R3 is located at a position closer to the resistor section R1 than the resistor section R4.

FIG. 16C shows a tenth example. In the tenth example, the magnetization direction of the ferromagnetic portion 72 of the magnetic field generator 70 is the same as that in the sixth example shown in FIG. 15B, but the arrangement of the resistor sections R1 to R4 is different from that in the sixth example. That is, in the tenth example, the resistor sections R1 to R4 are arranged in one direction parallel to the second direction D2 in the order of the resistor section R1, the resistor section R3, the resistor section R4, and the resistor section R2.

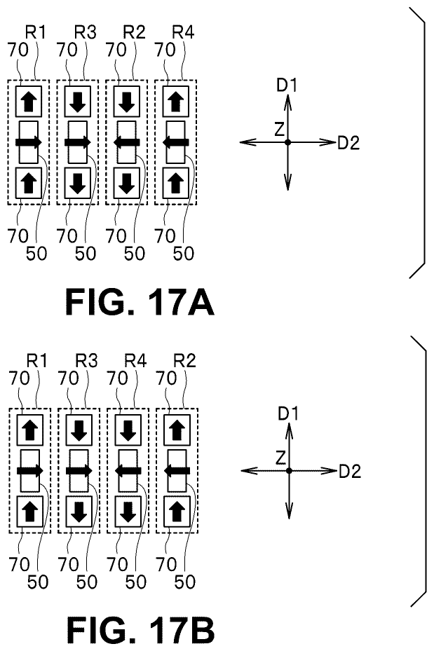

FIG. 17A shows an eleventh example. In the eleventh example, the arrangement of the resistor sections R1 to R4 is the same as that in the ninth example shown in FIG. 16B, and the magnetization direction of the ferromagnetic portion 72 of the magnetic field generator 70 is the same as that in the sixth example shown in FIG. 15B.

FIG. 17B shows a twelfth example. In the twelfth example, the arrangement of the resistor sections R1 to R4 is the same as that in the tenth example shown in FIG. 16C, and the magnetization direction of the ferromagnetic portion 72 of the magnetic field generator 70 is the same as that in the fifth example shown in FIG. 15A.

### Modification Examples

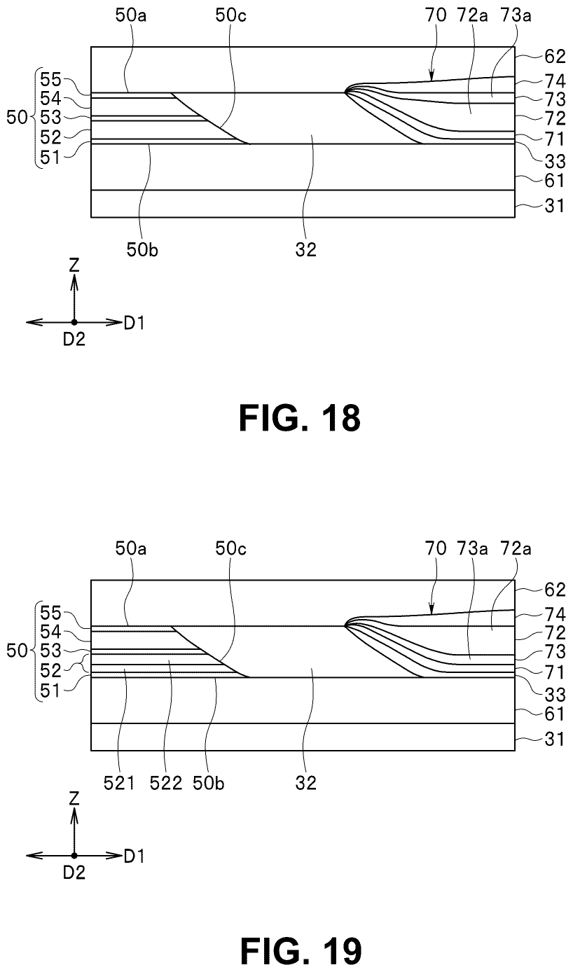

Next, first through fifth modification examples of the magnetic sensor 1 according to the example embodiment are described. Initially, the first modification example is described with reference to FIG. 18. FIG. 18 is a cross-sectional view showing a main part of the first modification example of the magnetic sensor 1. In the first modification example, the magnetization pinned layer 52 of the MR element 50 does not include the antiferromagnetic layer 521 shown in FIG. 8. In the first modification example, the magnetization pinned layer 52 may include a soft magnetic layer made of a ferromagnetic material containing one or more elements selected from the group consisting of Co, Fe, and Ni. In this case, the coercivity of the magnetization pinned layer 52 may be increased by using a specific material such as Ta for the buffer layer 51 and by reducing the thickness of the soft magnetic layer. Alternatively, the magnetization pinned layer 52 may be constituted of a hard magnetic material containing elements such as, for example Pt, Sm, and Nd.

In the process of fixing the magnetization direction of the magnetization pinned layer 52 in the first modification example, the magnetization direction of the initial magnetization pinned layer is fixed in a predetermined direction by using laser light and an external magnetic field that contains a component in the predetermined direction. In the plurality of initial MR elements that later become the plurality of MR elements 50A constituting the resistor sections R11 and R13 of the first detection circuit 10, the plurality of initial MR elements are irradiated with the laser light while applying an external magnetic field in the X direction thereto. The irradiation of the laser light decreases the coercivity of the magnetization pinned layer 52 of each of the plurality of initial MR elements, inclining the magnetization direction of the magnetization pinned layer 52 toward the X direction. After the irradiation of the laser light, the magnetization direction of the initial magnetization pinned layer is fixed in the X direction. This causes the initial magnetization pinned layer to become the magnetization pinned layer 52. Note that the coercivity of the magnetization pinned layer 52 of each of the plurality of initial MR elements that are not irradiated with the laser light is maintained at a magnitude such that the magnetization direction of the magnetization pinned layer 52 is not inclined by the external magnetic field.

In the plurality of initial MR elements that later become the plurality of MR elements 50A constituting the resistor sections R12 and R14 of the first detection circuit 10, the magnetization direction of the initial magnetization pinned layer of each of the plurality of initial MR elements can be fixed in the −X direction by using an external magnetic field in the −X direction. The magnetization direction of the magnetization pinned layer 52 of each of a plurality of MR elements 50B constituting each of the resistor sections R21 to R24 of the second detection circuit 20 is also fixed by the same method as with the magnetization pinned layer 52 of each of the plurality of MR elements 50A.

Next, a second modification example is described with reference to FIG. 19. FIG. 19 is a cross-sectional view showing a main part of the second modification example of the magnetic sensor 1. In the second modification example, the antiferromagnetic layer 73a, the ferromagnetic layer 72a, and the cap layer 74 are disposed in order on the buffer layer 71. In the second modification example, the antiferromagnetic layer 73a is in contact with the bottom surface of the ferromagnetic layer 72a to be exchange-coupled with the ferromagnetic layer 72a. This defines the magnetization direction of the ferromagnetic layer 72a.

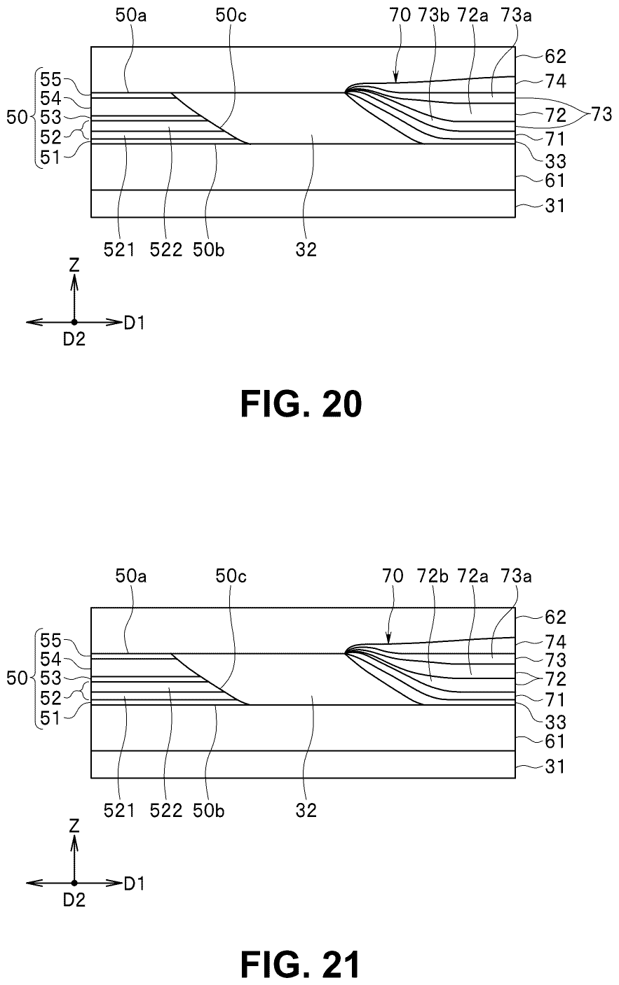

Next, a third modification example is described with reference to FIG. 20. FIG. 20 is a cross-sectional view showing a main part of the third modification example of the magnetic sensor 1. In the third modification example, the antiferromagnetic portion 73 includes an antiferromagnetic layer 73b in addition to the antiferromagnetic layer 73a. The antiferromagnetic layer 73b is disposed between the buffer layer 71 and the ferromagnetic layer 72a. The antiferromagnetic layer 73b is formed of an antiferromagnetic material such as, for example, IrMn or PtMn.

The antiferromagnetic layer 73b is in contact with the bottom surface of the ferromagnetic layer 72a to be exchange-coupled with the ferromagnetic layer 72a. As previously mentioned, the antiferromagnetic layer 73a is in contact with the top surface of the ferromagnetic layer 72a to be exchange-coupled with the ferromagnetic layer 72a. In the third modification example, the antiferromagnetic layer 73a and the antiferromagnetic layer 73b are exchange-coupled with the ferromagnetic layer 72a, to define the magnetization direction of the ferromagnetic layer 72a.

Next, a fourth modification example is described with reference to FIG. 21. FIG. 21 is a cross-sectional view showing a main part of the fourth modification example of the magnetic sensor 1. In the fourth modification example, the ferromagnetic portion 72 includes a ferromagnetic layer 72b in addition to the ferromagnetic layer 72a. The ferromagnetic layer 72b is disposed between the buffer layer 71 and the ferromagnetic layer 72a. The ferromagnetic layer 72b is formed of a ferromagnetic material containing one or more elements selected from the group consisting of Co, Fe, and Ni. In the fourth modification example, the ferromagnetic layer 72b has a magnetization in the same direction as the magnetization of the ferromagnetic layer 72a.

In the fourth modification example, the ferromagnetic layer 72a may be formed of a ferromagnetic material capable of increasing the exchange coupling energy with the antiferromagnetic layer 73a, and the ferromagnetic layer 72b may be formed of a ferromagnetic material having a saturation magnetic flux density larger than that of the ferromagnetic material constituting the ferromagnetic layer 72a. In this case, the strength of the bias magnetic field generated by the magnetic field generator 70 can be increased while increasing the exchange coupling energy between the ferromagnetic portion 72 including the ferromagnetic layers 72a and 72b and the antiferromagnetic layer 73a, and the magnetic field generator 70 can be made smaller. Examples of the ferromagnetic layer 72a include a Co₇₀Fe₃₀ layer. Examples of the ferromagnetic layer 72b include a Co₃₀Fe₇₀ layer. Note that Co₇₀Fe₃₀ represents an alloy containing 70 atomic percent Co and 30 atomic percent Fe, and Co₃₀Fe₇₀ represents an alloy containing 30 atomic percent Co and 70 atomic percent Fe.

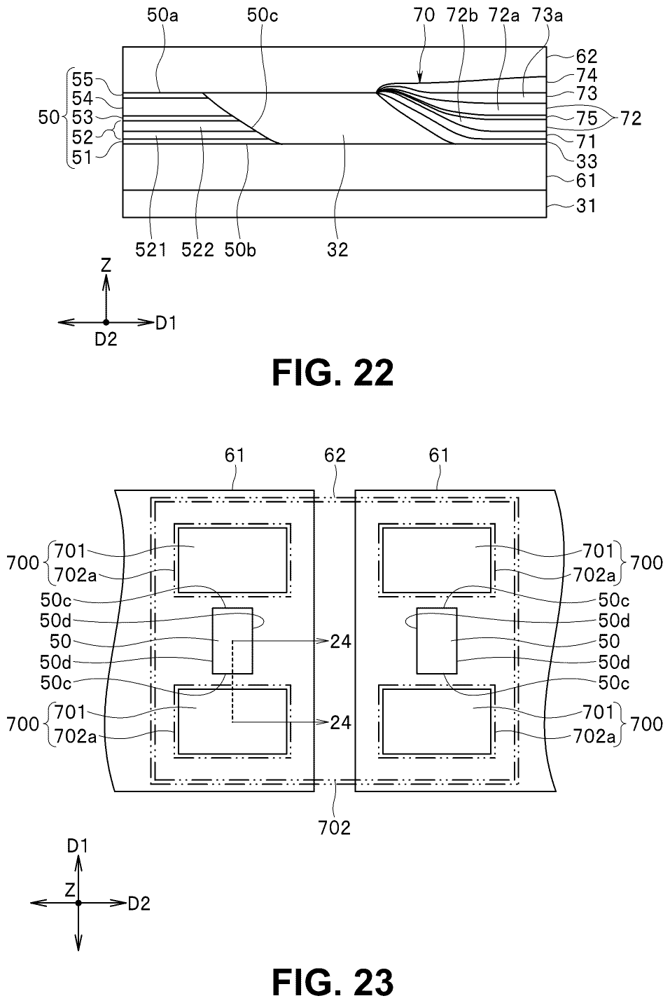

Next, a fifth modification example is described with reference to FIG. 22. FIG. 22 is a cross-sectional view showing a main part of the fifth modification example of the magnetic sensor 1. In the fifth modification example, the ferromagnetic portion 72 includes a ferromagnetic layer 72b in addition to the ferromagnetic layer 72a. The ferromagnetic layer 72b is disposed between the buffer layer 71 and the ferromagnetic layer 72a. The ferromagnetic layer 72b is formed of a ferromagnetic material containing one or more elements selected from the group consisting of Co, Fe, and Ni. The ferromagnetic layer 72a and the ferromagnetic layer 72b may be formed of a same ferromagnetic material or different ferromagnetic materials.

In the fifth modification example, the magnetic field generator 70 further includes a nonmagnetic layer 75 disposed between the ferromagnetic layer 72a and the ferromagnetic layer 72b. The nonmagnetic layer 75 is formed of a nonmagnetic metallic material such as, for example, Ru.

In the fifth modification example, the ferromagnetic layer 72a and the ferromagnetic layer 72b may be ferromagnetically exchange-coupled with each other via the nonmagnetic layer 75 so as to have the same magnetization direction. In this case, the ferromagnetic layer 72a and the ferromagnetic layer 72b have a magnetization in the same direction. The thickness of the nonmagnetic layer 75 is set to a thickness such that the exchange coupling between the ferromagnetic layer 72a and the ferromagnetic layer 72b is not lost. Providing the nonmagnetic layer 75 enables to adjust the coercivity of the ferromagnetic portion 72 and to adjust the surface roughness of the base of the ferromagnetic layer 72a.

Alternatively, the ferromagnetic layer 72a and the ferromagnetic layer 72b may be antiferromagnetically exchange-coupled with each other via the nonmagnetic layer 75 by the RKKY interaction. In this case, the magnetization direction of the ferromagnetic layer 72a and the magnetization direction of the ferromagnetic layer 72b are opposite to each other. The magnetization direction of the ferromagnetic portion 72 is the same as the magnetization direction of the ferromagnetic layer 72a. When the ferromagnetic layer 72a and the ferromagnetic layer 72b are antiferromagnetically exchange-coupled with each other, the net moment of the ferromagnetic portion 72 becomes small. Therefore, in the ferromagnetic portion 72, the Zeeman energy, which is the energy produced by the external magnetic field acting on the magnetic moment, becomes small. As a result, even when an external magnetic field is applied, the magnetization direction of the ferromagnetic portion 72 is less likely to incline than when the Zeeman energy is large.

The thickness of the nonmagnetic layer 75 is set so that the respective magnetization directions of the ferromagnetic layer 72a and the ferromagnetic layer 72b due to the RKKY interaction become expected directions, and the strength of the exchange coupling by the RKKY interaction becomes an expected strength.

### Second Example Embodiment

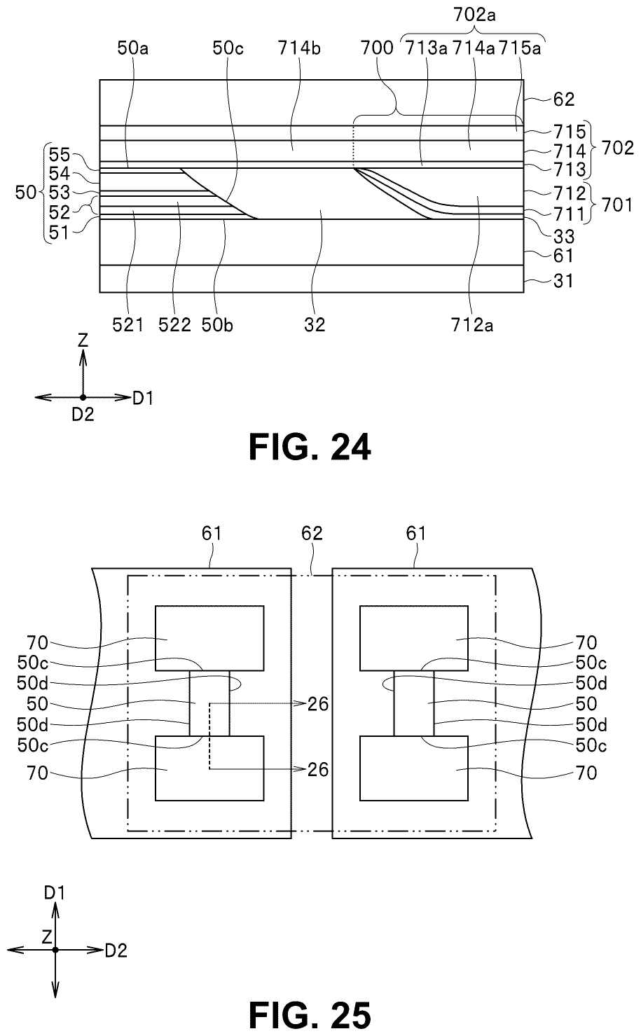

Next, a second example embodiment of the technology is described with reference to FIGS. 23 and 24. FIG. 23 is a plan view showing a main part of a magnetic sensor according to the example embodiment. FIG. 24 is a cross-sectional view showing a part of a cross section at a position indicated by a 24-24 line in FIG. 23. The magnetic sensor 1 according to the example embodiment includes a plurality of magnetic field generators 700 instead of the plurality of magnetic field generators 70 in the first example embodiment. The function of the plurality of magnetic field generators 700 and the positional relationship of the plurality of magnetic field generators 700 with respect to the plurality of MR elements 50 are the same as those in the first example embodiment.

Hereinafter, a configuration of the magnetic field generator 700 is described with a focus on one MR element 50. The magnetic sensor 1 according to the example embodiment includes two magnetic field generators 700 disposed with the MR element 50 interposed therebetween. Each of the two magnetic field generators 700 includes a ferromagnetic portion 712 made of a ferromagnetic material.

The ferromagnetic portion 712 includes a ferromagnetic layer 712a made of a ferromagnetic material. The ferromagnetic layer 712a is disposed to overlap the MR element 50 when viewed from the first direction D1. In the example embodiment in particular, the ferromagnetic layer 712a is disposed to overlap the entirety of the free layer 54 when viewed from the first direction D1. The MR element 50 is disposed between two ferromagnetic layers 712a located at a predetermined distance from each other in the first direction D1. The ferromagnetic layer 712a may be formed of, for example, the same material as of the ferromagnetic layer 72a in the first example embodiment.

Each of the two magnetic field generators 700 further includes a buffer layer 711 disposed on the bottom surface side of the ferromagnetic portion 712. The buffer layer 711 may be formed of, for example, the same material as of the buffer layer 71 in the first example embodiment.

The magnetic sensor 1 according to the example embodiment further includes an underlying layer 713 disposed on the MR element 50, the two ferromagnetic layers 712a, and the insulating layer 32, an antiferromagnetic layer 714 disposed on the underlying layer 713, and a cap layer 715 disposed on the antiferromagnetic layer 714. The antiferromagnetic layer 714 includes two facing parts 714a that respectively face the two ferromagnetic layers 712a via the underlying layer 713, and a non-facing part 714b that faces the MR element 50 and the insulating layer 32 via the underlying layer 713 but does not face the two ferromagnetic layers 712a. The two facing parts 714a are connected to each other by the non-facing part 714b.

The underlying layer 713 includes two interposing portions 713a interposed between the two ferromagnetic layers 712a and the two facing parts 714a. The cap layer 715 includes two protective portions 715a disposed on the two facing parts 714a.

The underlying layer 713 is formed of a metallic material. In the example embodiment in particular, the underlying layer 713 is formed of a ferromagnetic metallic material. If the underlying layer 713 is formed of a ferromagnetic metallic material, the underlying layer 713 may be formed of the same material as of the ferromagnetic layer 712a. Note that in the underlying layer 713, at least the interposing portion 713a may have magnetism. The part of the underlying layer 713 that is interposed between the MR element 50 and the insulating layer 32, and the antiferromagnetic layer 714 may or may not have magnetism.

The antiferromagnetic layer 714 may be formed of, for example, a material same as of the antiferromagnetic layer 73a in the first example embodiment. The cap layer 715 may be formed of, for example, a material same as of the cap layer 74 in the first example embodiment.

The buffer layer 711 and the ferromagnetic layer 712a constitute a first stack 701. The underlying layer 713, the antiferromagnetic layer 714, and the cap layer 715 constitute a second stack 702. The MR element 50 is disposed between the two first stacks 701. The second stack 702 is disposed on the MR element 50, the insulating layer 32, and the two first stacks 701.

The second stack 702 includes two stacked parts 702a disposed on the two first stacks 701. Each of the two stacked parts 702a includes the interposing portion 713a, a facing part 714a, and a protective portion 715a.

In a stack including the first stack 701 and a stacked part 702a disposed on the first stack 701, the facing part 714a is exchange-coupled with the ferromagnetic layer 712a via the interposing portion 713a. This defines the magnetization direction of the ferromagnetic layer 712a.

Each of the two magnetic field generators 700 further includes an antiferromagnetic portion made of an antiferromagnetic material. In the example embodiment, substantially the entirety of the antiferromagnetic portion is constituted of the facing part 714a. In the example embodiment, substantially the entirety of the ferromagnetic portion 712 is constituted of the ferromagnetic layer 712a. The facing part 714a is exchange-coupled with the ferromagnetic layer 712a, and thereby the antiferromagnetic portion is exchange-coupled with the ferromagnetic portion 712. This defines the magnetization direction of the ferromagnetic portion 712. The magnetization direction of the ferromagnetic portion 712 coincides with the magnetization direction of the ferromagnetic layer 712a. The ferromagnetic portion 712 and the antiferromagnetic portion generate a bias magnetic field based on the magnetization of the ferromagnetic portion 712. The bias magnetic field is applied to the MR element 50.

Since the ferromagnetic layer 712a is a part of the first stack 701 and the facing part 714a is a part of the stacked part 702a, it can be said that the first stack 701 and the stacked part 702a constitute the magnetic field generator 700. The magnetic field generator 700 includes the buffer layer 711, the ferromagnetic layer 712a, the interposing portion 713a, the facing part 714a, and the protective portion 715a.

The MR element 50 is disposed between two magnetic field generators 700. The two magnetic field generators 700 cooperate to apply a bias magnetic field to the MR element 50. The magnetization direction of the ferromagnetic layer 712a of one of the two magnetic field generators 700 may be the same as the magnetization direction of the ferromagnetic layer 712a of the other of the two magnetic field generators 700. In this case, the direction of the bias magnetic field generated by one of the two magnetic field generators 700 becomes the same as the direction of the bias magnetic field generated by the other of the two magnetic field generators 700.

If the underlying layer 713 is formed of a same material as the ferromagnetic layer 712a, the ferromagnetic layer 712a and the interposing portion 713a constitute substantially one ferromagnetic layer. The facing part 714a contacts the top surface of this one ferromagnetic layer to be exchange-coupled with this one ferromagnetic layer.

The maximum dimension of the ferromagnetic layer 712a in the stacking direction (direction parallel to the Z direction) of the plurality of magnetic films may be larger than the maximum dimension of the underlying layer 713 in the stacking direction. The maximum dimension of the free layer 54 in the stacking direction is larger than the maximum dimension of the underlying layer 713 in the stacking direction.

The top surface 50a of the MR element 50 faces the non-facing part 714b of the antiferromagnetic layer 714. The distance between the non-facing part 714b and the bottom surface 50b of the MR element 50 is larger than the distance between the top surface 50a and the bottom surface 50b. The distance between the facing part 714a of the antiferromagnetic layer 714 and the top surface of the lower electrode 61 may be the same as the distance between the non-facing part 714b and the bottom surface 50b, or may be different from the distance between the non-facing part 714b and the bottom surface 50b. In the latter case, the maximum distance between the facing part 714a and the top surface of the lower electrode 61 may be larger than the distance between the non-facing part 714b and the bottom surface 50b.

The top surface of the second stack 702, i.e., the top surface of the cap layer 715, is in contact with the upper electrode 62. The planar shape of the second stack 702 (shape viewed from the Z direction) may coincide with, may be smaller than, or may be larger than the planar shape of the upper electrode 62.

Heretofore, the configuration of the magnetic field generator 700 has been described with a focus on one MR element 50. In the example embodiment, the magnetic sensor 1 includes the plurality of MR elements 50. As shown in FIG. 23, the plurality of MR elements 50 includes two MR elements 50 arranged along the second direction D2. The second stack 702 is interposed between the two MR elements 50 and the upper electrode 62 electrically connecting the two MR elements 50. In the example shown in FIG. 23, the second stack 702 is disposed on the two MR elements 50 and four first stacks 701. In this example, the second stack 702 includes four stacked parts 702a.

The two MR elements 50 are electrically connected also by the antiferromagnetic layer 714 of the second stack 702. The two MR elements 50 are connected in series by the antiferromagnetic layer 714.

In the example embodiment, since the magnetic sensor 1 includes the plurality of MR elements 50 and the plurality of magnetic field generators 700, the magnetic sensor 1 includes a plurality of underlying layers 713, a plurality of antiferromagnetic layers 714, and a plurality of cap layers 715.

Next, a process of forming the plurality of magnetic field generators 700 in the example embodiment is described. Here, a process of forming two magnetic field generators 700 described with a focus on one MR element 50. First, a photoresist mask is formed on the MR element 50 and the insulating layer 32. Next, the insulating layer 32 is etched. Next, while leaving the photoresist mask in place, the insulating layer 33, the buffer layer 711, and an initial ferromagnetic layer that later becomes the ferromagnetic layer 712a are formed in order. Next, the photoresist mask is removed. Next, the underlying layer 713, the antiferromagnetic layer 714, and the cap layer 715 are formed in order over the MR element 50, the ferromagnetic layer 712a, and the insulating layer 32. Next, a process of fixing the magnetization direction of the initial ferromagnetic layer is performed. The process of fixing the magnetization direction of the initial ferromagnetic layer is the same as the process of fixing the magnetization direction of the ferromagnetic portion 72 in the first example embodiment. The fixation of the magnetization direction of the initial ferromagnetic layer causes the initial ferromagnetic layer to become the ferromagnetic layer 712a, and completes the magnetic field generator 700.

Note that the ferromagnetic portion 712 of the magnetic field generator 700 in the example embodiment may include two ferromagnetic layers, as in the fourth and fifth modification examples in the first example embodiment. If the ferromagnetic portion 712 includes two ferromagnetic layers, the magnetic field generator 700 may include a nonmagnetic layer disposed between the two ferromagnetic layers, as in the fifth modification example in the first example embodiment.

The antiferromagnetic portion of the magnetic field generator 700 in the example embodiment may also include, in addition to the facing part 714a, an antiferromagnetic layer disposed between the buffer layer 711 and the ferromagnetic layer 712a, as in the third modification example in the first example embodiment.

The configuration, operation, and effects of the present example embodiment are otherwise the same as those of the first example embodiment.

### Third Example Embodiment

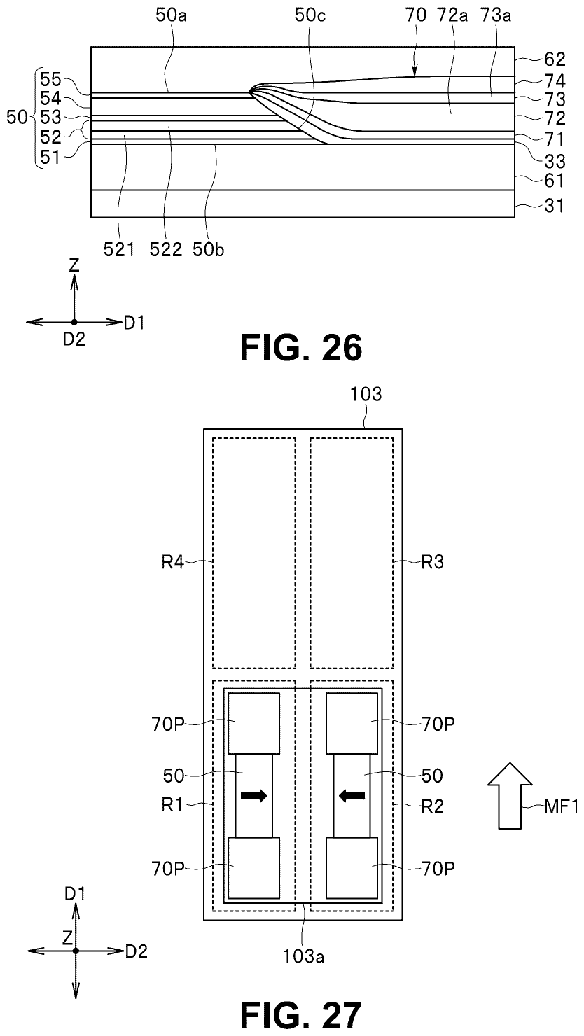

Next, a third example embodiment of the technology is described with reference to FIGS. 25 and 26. FIG. 25 is a plan view showing a main part of a magnetic sensor according to the example embodiment. FIG. 26 is a cross-sectional view showing a part of a cross section at a position indicated by a 26-26 line in FIG. 25.

The following describes, with a focus on one MR element 50, how the configuration of the magnetic sensor 1 according to the example embodiment differs from that in the first example embodiment. In the example embodiment, each of the two magnetic field generators 70 is located closer to the MR element 50 than in the first example embodiment. In the example embodiment in particular, each of the two magnetic field generators 70 is disposed to ride up on a side surface 50c of the MR element 50. A part of each of the two magnetic field generators 70 overlaps a part of the MR element 50 when viewed from the Z direction. The insulating layer 33 is interposed between the MR element 50 and the two magnetic field generators 70.

Note that FIG. 26 shows an example in which the configuration of each of the two magnetic field generators 70 is the same as the configuration described with reference to FIG. 8 in the first example embodiment. However, the configuration of each of the two magnetic field generators 70 may be the same as the configuration in any of the plurality of modification examples of the first example embodiment. In particular, if the configuration of each of the two magnetic field generators 70 is the same as the configuration in the fifth modification example of the first example embodiment described with reference to FIG. 22, and the ferromagnetic layer 72a and the ferromagnetic layer 72b are antiferromagnetically exchange-coupled with each other via the nonmagnetic layer 75, the following effects are achieved. The strength of the bias magnetic field based on the ferromagnetic layer 72a or the ferromagnetic layer 72b is greater than the strength of the bias magnetic field based on the entirety of the ferromagnetic portion 72. In the example embodiment, the distance between the free layer 54 of the MR element 50 and the ferromagnetic layer 72a or the ferromagnetic layer 72b becomes smaller than that in the example shown in FIG. 22. Therefore, the free layer 54 can be applied with a bias magnetic field based on the ferromagnetic layer 72a or the ferromagnetic layer 72b and having a strength greater than the strength of the bias magnetic field based on the entirety of the ferromagnetic portion 72.

Next, a process of forming the plurality of magnetic field generators 70 in the example embodiment is described. Here, a process of forming the two magnetic field generators 70 is described with a focus on one MR element 50. First, a first photoresist mask is formed on the stacked film that later becomes the MR element 50. Next, the stacked film is patterned by etching using the first photoresist mask so that the two side surfaces 50d (see FIG. 25) are formed on the stacked film. Next, while leaving the first photoresist mask in place, the insulating layer 32 is formed around the stacked film. Next, the first photoresist mask is removed.

Next, a second photoresist mask is formed on the stacked film and the insulating layer 32. Next, the stacked film is patterned by etching using the second photoresist mask so that the two side surfaces 50c (see FIG. 25) are formed on the stacked film. In this etching, the insulating layer 32 is also etched. The formation of the two side surfaces 50c on the stacked film causes the stacked film to become the MR element 50. Next, while leaving the second photoresist mask in place, the insulating layer 33 and the two initial magnetic field generators 70P that later become the two magnetic field generators 70 are formed in order. The configuration of the two initial magnetic field generators 70P is the same as that in the first example embodiment. Next, the second photoresist mask is removed.

Next, the magnetization direction of the initial ferromagnetic portion of each of the two initial magnetic field generators 70P is fixed. The method of fixing the magnetization direction of the initial ferromagnetic portion in the example embodiment is basically the same as that in the first example embodiment.

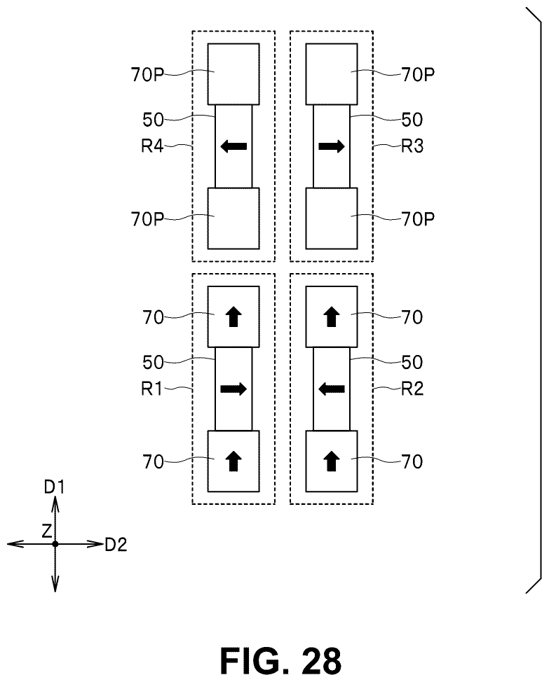

The method of fixing the magnetization direction of the initial ferromagnetic portion in the example embodiment is described in detail below with reference to FIGS. 27 through 30. First, as shown in FIG. 27, the plurality of initial magnetic field generators 70P corresponding to the resistor sections R1 and R2 are selectively irradiated with the laser light while applying the magnetic field component MF1 in one direction parallel to the first direction D1 (direction from bottom to top in FIG. 27) to the magnetic sensor 1. After the irradiation of the laser light, the magnetization direction of the initial ferromagnetic portion of each of the irradiated plurality of initial magnetic field generators 70P is fixed in the same direction as the magnetic field component MF1. This causes the plurality of initial magnetic field generators 70P irradiated with the laser light to become the plurality of magnetic field generators 70, as shown in FIG. 28.

The plurality of initial magnetic field generators 70P may be selectively irradiated with the laser light by using a mask 103, for example. The mask 103 has at least one opening 103a that exposes some or all of the plurality of initial magnetic field generators 70P corresponding to the resistor sections R1 and R2. In the example embodiment in particular, some or all of the plurality of MR elements 50 of the resistor sections R1 and R2 are also exposed through the at least one opening 103a. The plurality of MR elements 50 of the resistor sections R3 and R4 and the plurality of initial magnetic field generators 70P corresponding to the resistor sections R3 and R4 are covered by the mask 103. The irradiation of the laser light is performed through the at least one opening 103a to some or all of the plurality of initial magnetic field generators 70P.

The plurality of MR elements 50 of the resistor sections R1 and R2 are also irradiated with the laser light. Therefore, during the irradiation of the laser light, the temperature of the plurality of MR elements 50 of the resistor sections R1 and R2 also rises. However, the magnetization direction of the magnetization pinned layer 52 of each of the plurality of MR elements 50 of the resistor sections R1 and R2 is maintained not to be inclined by the magnetic field component MF1. To maintain the magnetization direction of the magnetization pinned layer 52, a structure may be used in which the magnetization pinned layer 52 does not have a temperature higher than the blocking temperature of the antiferromagnetic layer 521, or the blocking temperature of the antiferromagnetic layer 521 may be made higher than that of the antiferromagnetic portion 73. Alternatively, to maintain the magnetization direction of the magnetization pinned layer 52, the strength of the magnetic field component MF1 may be restrained to a magnitude at a level where the magnetization direction of the magnetization pinned layer 52 does not incline, or a structure may be used in which the coercivity of the magnetization pinned layer 52 is increased or in which it is made difficult for the magnetization direction of the magnetization pinned layer 52 to move.

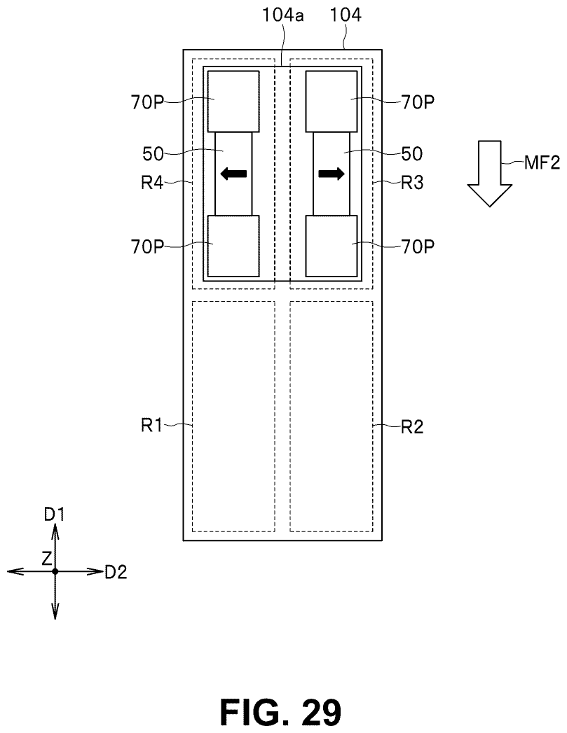

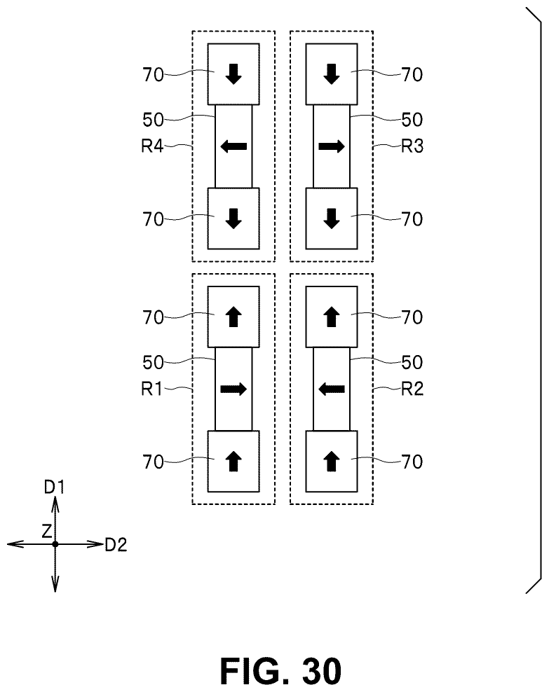

FIG. 29 shows the next process. In this process, the plurality of initial magnetic field generators 70P corresponding to the resistor sections R3 and R4 are selectively irradiated with laser light, while applying the magnetic field component MF2 in one other direction parallel to the first direction D1 (direction from top to bottom in FIG. 29) to the magnetic sensor 1. After the irradiation of the laser light, the magnetization direction of the initial ferromagnetic portions of each of the irradiated plurality of initial magnetic field generators 70P is fixed in the same direction as the magnetic field component MF2. This causes the plurality of initial magnetic field generators 70P irradiated with the laser light to become the plurality of magnetic field generators 70, as shown in FIG. 30.

As in the process shown in FIG. 27, the plurality of initial magnetic field generators 70P may be selectively irradiated with laser light by using a mask 104, for example. The mask 104 includes at least one opening 104a that exposes some or all of the plurality of initial magnetic field generators 70P corresponding to the resistor sections R3 and R4. In the example embodiment in particular, some or all of the plurality of MR elements 50 of the resistor sections R3 and R4 are also exposed through the at least one opening 104a. The plurality of MR elements 50 of the resistor sections R1 and R2 and the plurality of magnetic field generators 70 corresponding to the resistor sections R1 and R2 are covered by the mask 104. The irradiation of the laser light is performed through the at least one opening 104a to some or all of the plurality of initial magnetic field generators 70P.

The plurality of MR elements 50 of the resistor sections R3 and R4 are also irradiated with the laser light. Therefore, during the irradiation of the laser light, the temperature of the plurality of MR elements 50 of the resistor sections R3 and R4 also rises. However, the magnetization direction of the magnetization pinned layer 52 of each of the plurality of MR elements 50 of the resistor sections R3 and R4 is maintained not to be inclined by the magnetic field component MF2, as with the magnetization direction of the magnetization pinned layer 52 of each of the plurality of MR elements 50 of the resistor sections R1 and R2.

The configuration, operation, and effects of the present example embodiment are otherwise the same as those of the first example embodiment.

### Modification Example

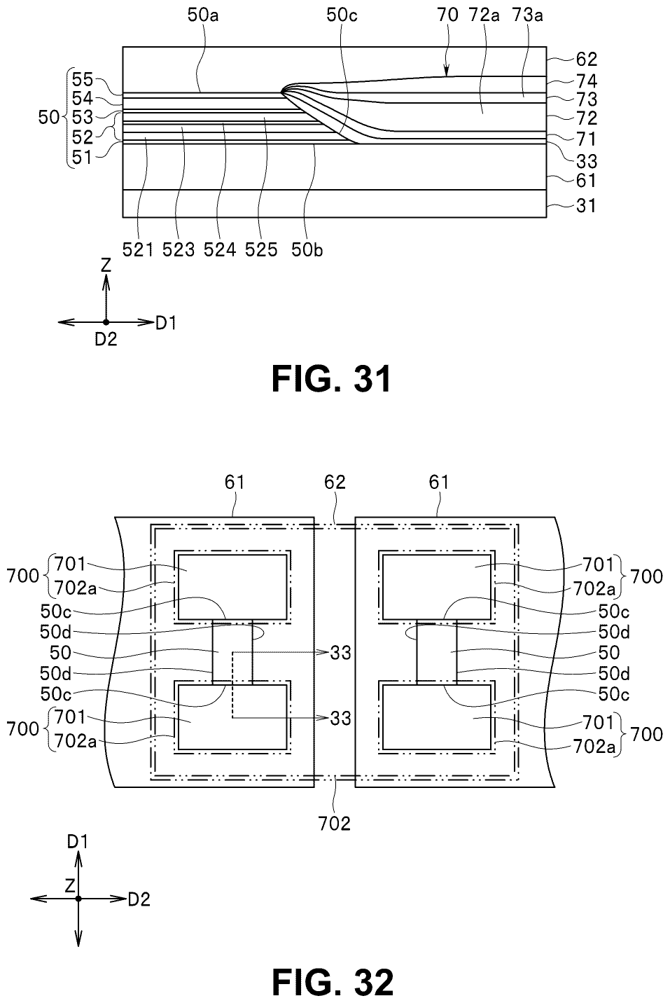

Next, a modification example of the magnetic sensor 1 according to the example embodiment is described with reference to FIG. 31. FIG. 31 is a cross-sectional view showing a main part of the modification example of the magnetic sensor 1 according to the example embodiment. In the modification example, the magnetization pinned layer 52 of the MR element 50 may include the antiferromagnetic layer 521 disposed on the buffer layer 51, a ferromagnetic layer 523 disposed on the antiferromagnetic layer 521, a nonmagnetic layer 524 disposed on the ferromagnetic layer 523, and a ferromagnetic layer 525 disposed on the nonmagnetic layer 524. The ferromagnetic layers 523 and 525 are formed of a ferromagnetic material containing one or more elements selected from the group consisting of Co, Fe, and Ni. The nonmagnetic layer 524 is formed of a nonmagnetic metallic material such as, for example, Ru.

The antiferromagnetic layer 521 may be formed of, for example, the same material as of the antiferromagnetic layer 521 shown in FIG. 18 in the first example embodiment. As in the first example embodiment, the antiferromagnetic layer 73a of the antiferromagnetic portion 73 of the magnetic field generator 70 and the antiferromagnetic layer 521 may contain a same element.

The antiferromagnetic layer 521 is exchange-coupled with the ferromagnetic layer 523 to fix the magnetization direction of the ferromagnetic layer 523. The ferromagnetic layer 523 and the ferromagnetic layer 525 are antiferromagnetically exchange-coupled with each other via the nonmagnetic layer 524. The magnetization direction of the ferromagnetic layer 523 and the magnetization direction of the ferromagnetic layer 525 are opposite each other. The magnetization direction of the magnetization pinned layer 52 is the same as the magnetization direction of the ferromagnetic layer 525.

In the modification example, since the magnetization direction of the ferromagnetic layer 523 and the magnetization direction of the ferromagnetic layer 525 are opposite each other, the net moment of the magnetization pinned layer 52 becomes small. Therefore, in the magnetization pinned layer 52, the Zeeman energy, which is the energy produced by the external magnetic field acting on the magnetic moment, becomes small. As a result, even if the temperature of the plurality of MR elements 50 rises due to the laser light to irradiate the initial magnetic field generator 70P with as in the example embodiment, the magnetization direction of the magnetization pinned layer 52 is less likely to incline toward the direction of the magnetic field component MF1 or the direction of the magnetic field component MF2 compared to when the Zeeman energy is large.

In the modification example, a magnetization amount Mst1 per unit area of the ferromagnetic layer 523 may be different from a magnetization amount Mst2 per unit area of the ferromagnetic layer 525. In the modification example in particular, the magnetization amount Mst1 may be less than or equal to the magnetization amount Mst2. If Mst1>Mst2, when the temperature of the plurality of MR elements 50 rises due to the laser light to irradiate the initial magnetic field generator 70P with, the magnetization direction of the ferromagnetic layer 523 may incline toward the direction of the magnetic field component MF1 or the direction of the magnetic field component MF2 regardless of the magnitude of the strength of the magnetic field component MF1 or the magnetic field component MF2.

In contrast, if Mst1≤Mst2, when the temperature of the plurality of MR elements 50 rises due to the laser light to irradiate the initial magnetic field generator 70P with, the magnetization direction of the ferromagnetic layer 523 may incline toward a direction opposite to the direction of the magnetic field component MF1 or the direction of the magnetic field component MF2 in a case where the strength of the magnetic field component MF1 or the magnetic field component MF2 is small. In this case, in a case where the strength of the magnetic field component MF1 or the magnetic field component MF2 is large, the magnetization direction of the ferromagnetic layer 523 inclines toward the direction of the magnetic field component MF1 or the direction of the magnetic field component MF2. Therefore, if Mst1≤Mst2, it is enabled to little change the magnetization direction of the ferromagnetic layer 523 by adjusting the strength of the magnetic field components MF1 and MF2 to an appropriate magnitude. This enables to restrain change of the magnetization direction of the magnetization pinned layer 52.

Note that even if Mst1>Mst2, when the coercivity of the ferromagnetic layer 523 is large, the magnetization direction of the magnetization pinned layer 52 is less likely to incline toward the direction of the magnetic field component MF1 or the direction of the magnetic field component MF2. Even if Mst1>Mst2, depending on the states of the magnetostriction of the ferromagnetic layer 523 and the stress around the MR element 50, the magnetization direction of the magnetization pinned layer 52 is less likely to incline toward the direction of the magnetic field component MF1 or the direction of the magnetic field component MF2.

### Fourth Example Embodiment

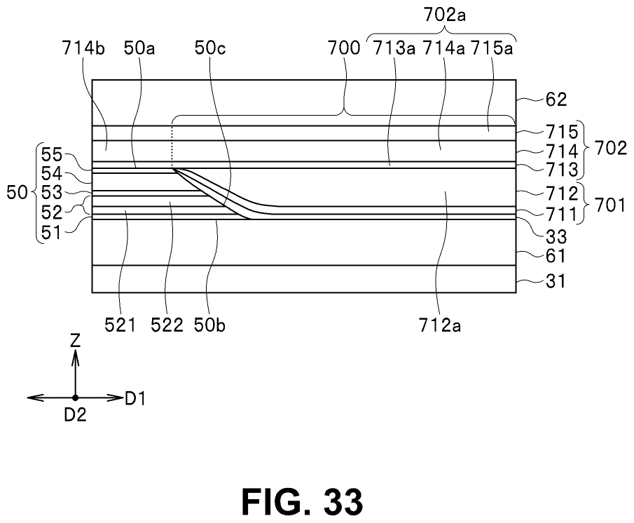

Next, a fourth example embodiment of the technology is described with reference to FIGS. 32 and 33. FIG. 32 is a plan view showing a main part of a magnetic sensor according to the example embodiment. FIG. 33 is a cross-sectional view showing a part of a cross section at a position indicated by a 33-33 line in FIG. 32. The following describes, with a focus on one MR element 50, how the configuration of the magnetic sensor 1 according to the example embodiment differs from that in the second example embodiment. In the example embodiment, each of the two magnetic field generators 700 is located closer to the MR element 50 than in the second example embodiment. In the example embodiment in particular, the ferromagnetic layer 712a of the ferromagnetic portion 712 of each of the two magnetic field generators 700 is disposed to ride up on the side surface 50c of the MR element 50. A part of the ferromagnetic layer 712a overlaps a part of the MR element 50 when viewed from the Z direction. An insulating layer 33 is interposed between the MR element 50 and the two magnetic field generators 700.

Next, a process of forming the plurality of magnetic field generators 700 in the example embodiment is described. Here, with a focus on one MR element 50, a process of forming the two magnetic field generators 700 is described. First, a photoresist mask is formed on a stacked film that later becomes the MR element 50 and on which the two side surfaces 50d (see FIG. 32) have been formed, and on the insulating layer 32. Next, the stacked film is patterned by etching using a photoresist mask so that the two side surfaces 50c (see FIG. 32) are formed on the stacked film. In this etching, the insulating layer 32 is also etched. The formation of the two side surfaces 50c on the stacked film causes the stacked film to become the MR element 50.

Next, while leaving the photoresist mask in place, the insulating layer 33, the buffer layer 711, and the initial ferromagnetic layer that later becomes the ferromagnetic layer 712a are formed in order. Next, the photoresist mask is removed. Next, the underlying layer 713, the antiferromagnetic layer 714, and the cap layer 715 are formed in this order over the MR element 50, the initial ferromagnetic layer, and the insulating layer 32. Next, a process of fixing the magnetization direction of the initial ferromagnetic layer is performed. The process of fixing the magnetization direction of the initial ferromagnetic layer is the same as that in the second example embodiment. The fixation of the magnetization direction of the initial ferromagnetic layer causes the initial ferromagnetic layer to become the ferromagnetic layer 712a, and completes the magnetic field generator 700.

The configuration, operation, and effects of the present example embodiment are otherwise the same as those of the second example embodiment.

### Modification Examples

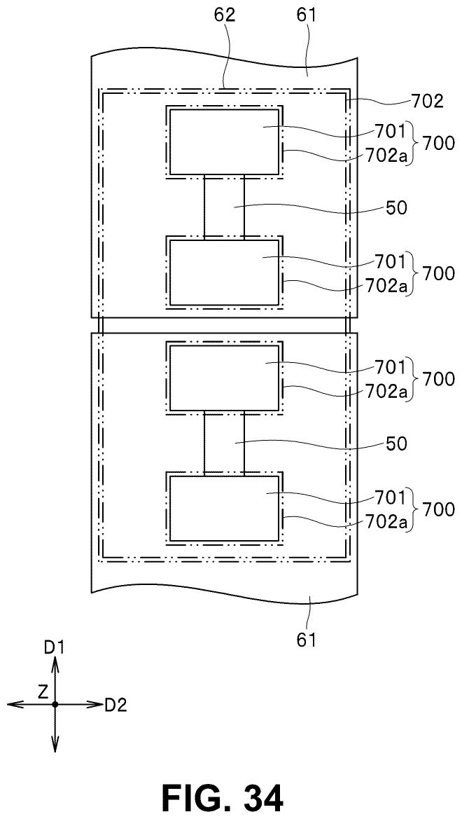

Next, first through third modification examples of the magnetic sensor 1 according to the example embodiment will be described. Initially, the first modification example is described with reference to FIG. 34. FIG. 34 is a plan view showing a main part of the first modification example of the magnetic sensor 1.

In the first modification example, each of the plurality of lower electrodes 61 electrically connects two adjacent MR elements 50 in the first direction D1. Each of the plurality of upper electrodes 62 electrically connects two adjacent MR elements 50 dispose on the two lower electrodes 61. This connects in series the plurality of MR elements 50 arranged in a row in the first direction D1. In the first modification example, the plurality of connecting electrodes electrically connect the plurality of lower electrodes 61 or the plurality of upper electrodes 62 so that a group of the plurality of MR elements 50 arranged in a row is connected in series.

In the first modification example, the second stack 702 is interposed between the two MR elements 50 arranged in the first direction D1 and the upper electrode 62. The two MR elements 50 are electrically connected also by the antiferromagnetic layer 714 (see FIG. 33) of the second stack 702. The two MR elements 50 are connected in series by the antiferromagnetic layer 714.

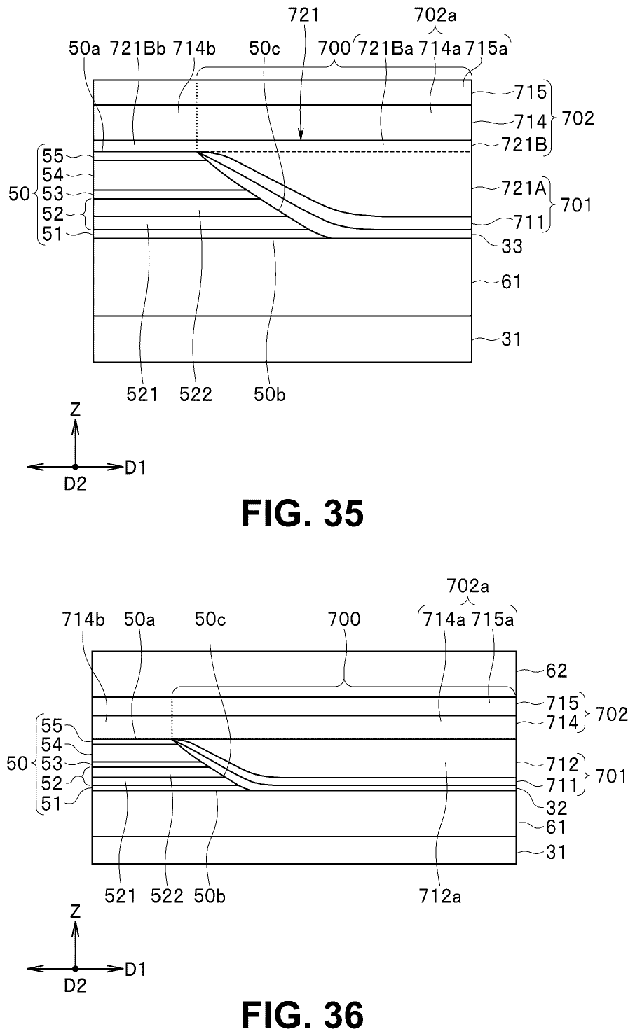

Next, the second modification example is described with reference to FIG. 35. FIG. 35 is a cross-sectional view showing a main part of the second modification example of the magnetic sensor 1. In the second modification example, the first stack 701 includes, instead of the ferromagnetic layer 712a, a ferromagnetic portion 721A made of a ferromagnetic material. The ferromagnetic portion 721A has the same function as that of the ferromagnetic portion 712. The shape and arrangement of the ferromagnetic portion 721A may be the same as the shape and arrangement of the ferromagnetic layer 712a.

The second stack 702 includes an underlying portion 721B instead of the underlying layer 713. The shape and arrangement of the underlying portion 721B may be the same as the shape and arrangement of the underlying layer 713. The underlying portion 721B includes an interposing portion 721Ba interposed between the ferromagnetic portion 721A and the facing part 714a, and a non-interposing portion 721Bb other than the interposing portion 721Ba. The stacked part 702a includes the interposing portion 721Ba instead of the interposing portion 713a.

In the second modification example in particular, the ferromagnetic portion 721A and the underlying portion 721B are constituted of one ferromagnetic layer 721. In FIG. 35, the boundary between the ferromagnetic portion 721A and the underlying portion 721B is indicated by a dashed line.

Next, the third modification example is described with reference to FIG. 36. FIG. 36 is a cross-sectional view showing a main part of the third modification example of the magnetic sensor 1. In the third modification example, the underlying layer 713 is not provided, and the antiferromagnetic layer 714 is disposed on the MR element 50, the two ferromagnetic layers 712a, and the insulating layer 32.

### Fifth Example Embodiment

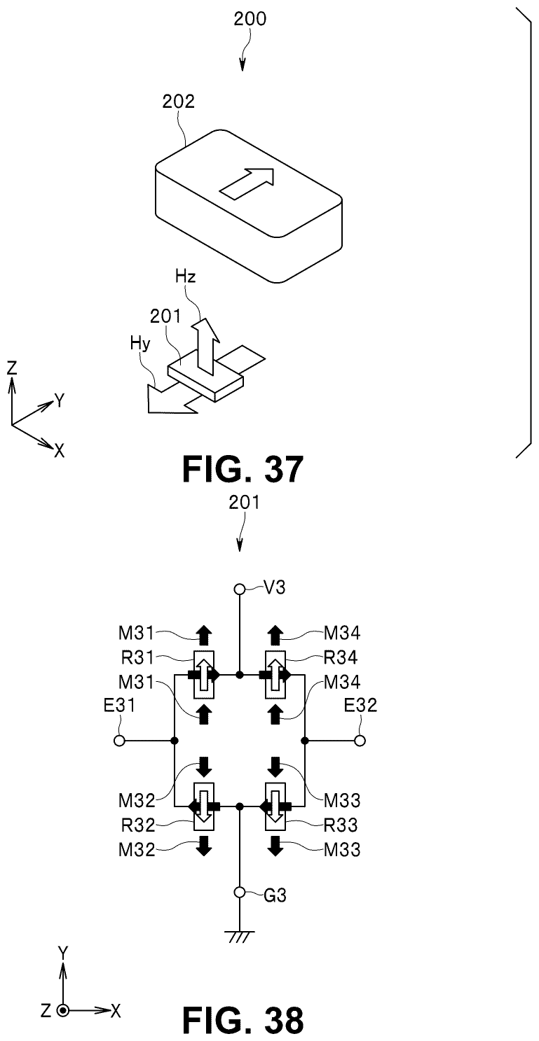

Next, a fifth example embodiment of the technology is described. Initially, a configuration of a magnetic sensor system including a magnetic sensor according to the example embodiment is described with reference to FIG. 37. FIG. 37 is a perspective view showing a magnetic sensor system 200 in the example embodiment.

The magnetic sensor system 200 includes a magnetic sensor 201 according to the example embodiment and a magnetic field generation section 202 that generates a predetermined magnetic field. In the example embodiment, the magnetic field generation section 202 is a magnet configured such that a partial magnetic field, which is a part of the generated magnetic field, is applied to the magnetic sensor 201. This partial magnetic field includes a first magnetic field component Hz parallel to the Z direction and a second magnetic field component Hy parallel to the Y direction.

As shown in FIG. 37, in the example embodiment, the magnetization direction of the magnetic field generation section 202 is the Y direction, and the direction of the second magnetic field component Hy is the −Y direction. The direction of the first magnetic field component Hz is the Z direction when the magnetic field generation section 202 moves in the Y direction from a predetermined position, and is the −Z direction when the magnetic field generation section 202 moves in the −Y direction from the predetermined position.

Next, a schematic configuration of the magnetic sensor 201 according to the example embodiment is described with reference to FIG. 38. FIG. 38 is a circuit diagram showing a circuit configuration of the magnetic sensor 201.

The magnetic sensor 201 includes four resistor sections R31, R32, R33, and R34, a power supply port V3, a ground port G3, and two output ports E31 and E32. The resistor section R31 is provided between the power supply port V3 and the output port E31. The resistor section R32 is provided between the output port E31 and the ground port G3. The resistor section R33 is provided between the output port E32 and the ground port G3. The resistor section R34 is provided between the power supply port V3 and the output port E32. A voltage or current of a predetermined magnitude is applied to the power supply port V3. The ground port G3 is connected to ground.

Each of the resistor sections R31 to R34 includes the plurality of MR elements 50. The plurality of MR elements 50 that constitute the resistor section R31 are provided between the power supply port V3 and the output port E31 in circuit configuration. The plurality of MR elements 50 that constitute the resistor section R32 are provided between the output port E31 and the ground port G3 in circuit configuration. The plurality of MR elements 50 that constitute the resistor section R33 are provided between the output port E32 and the ground port G3 in circuit configuration. The plurality of MR elements 50 that constitute the resistor section R34 are provided between the power supply port V3 and the output port E32 in circuit configuration.

The configuration of the plurality of MR elements 50 is the same as that in the third example embodiment. That is, each of the plurality of MR elements 50 includes the buffer layer 51, the magnetization pinned layer 52, the gap layer 53, the free layer 54, and the cap layer 55, as shown in FIG. 26 in the third example embodiment.

In FIG. 38, arrows drawn to overlap the resistor sections R31 to R34, respectively, represent the magnetization direction of the magnetization pinned layer 52 in each of the resistor sections R31 to R34. In the example shown in FIG. 38, the direction of the main component of the magnetization of the magnetization pinned layer 52 in each of the resistor sections R31 and R34 is the X direction. The direction of the main component of the magnetization of the magnetization pinned layer 52 in each of the resistor sections R32 and R33 is the −X direction. The free layer 54 in each of the resistor sections R31 to R34 has shape anisotropy in which the direction of the magnetization easy axis is parallel to the Y direction.

The magnetic sensor 201 further includes the plurality of magnetic field generators 70. The configuration of the plurality of magnetic field generators 70 is the same as in the third example embodiment. The plurality of magnetic field generators 70 include a plurality of pairs of the magnetic field generators 70, each pair including two magnetic field generators 70. The above two magnetic field generators 70 are disposed at a predetermined distance from each other in a direction parallel to the Y direction with one MR element 50 interposed therebetween. The two magnetic field generators 70 are configured to apply a bias magnetic field to the one MR element 50 located therebetween. This bias magnetic field includes a component parallel to the Y direction as a main component.

In FIG. 38, arrows labelled with reference numerals M31, M32, M33, and M34 indicate the directions of the main components of the bias magnetic fields generated by the plurality of magnetic field generators 70 at the resistor sections R31, R32, R33, and R34, respectively. The directions of the main components of the bias magnetic fields at the resistor sections R31 and R34 are each the Y direction. The directions of the main components of the bias magnetic fields at the resistor sections R32 and R33 are each the −Y direction.

The direction of the bias magnetic field substantially indicates the magnetization direction of the ferromagnetic portion 72 of the plurality of magnetic field generators 70. The magnetization direction of the ferromagnetic portion 72 of the plurality of magnetic field generators 70 corresponding to the resistor sections R31 and R34 is the Y direction. The magnetization direction of the ferromagnetic portion 72 of the plurality of magnetic field generators 70 corresponding to the resistor sections R32 and R33 is the −Y direction.

In FIG. 38, the plurality of hollow arrows drawn to overlap the resistor sections R31 to R34, respectively, represent the magnetization direction of the free layer in each of the resistor sections R31 to R34 in a case where the partial magnetic field is not applied to the magnetic sensor 201. The direction of the main component of the magnetization of the free layer in each of the resistor sections R31 and R34 may be the Y direction, and may be the same as the direction of the main component of the bias magnetic field at the resistor sections R31 and R34. The direction of the main component of the magnetization of the free layer in each of the resistor sections R32 and R33 may be the −Y direction, and may be the same as the direction of the main component of the bias magnetic field at the resistor sections R32 and R33.

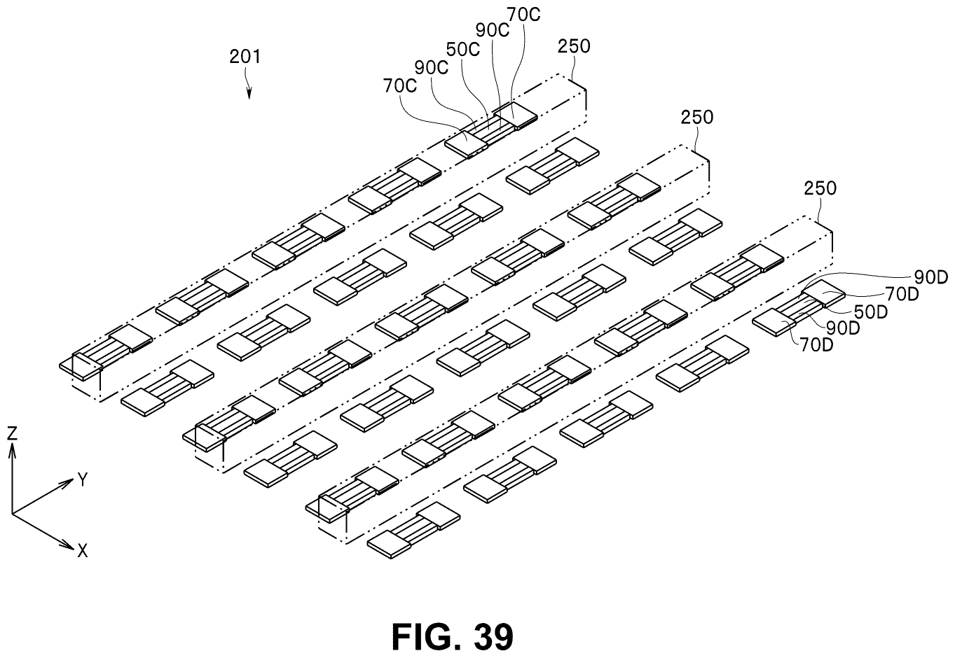

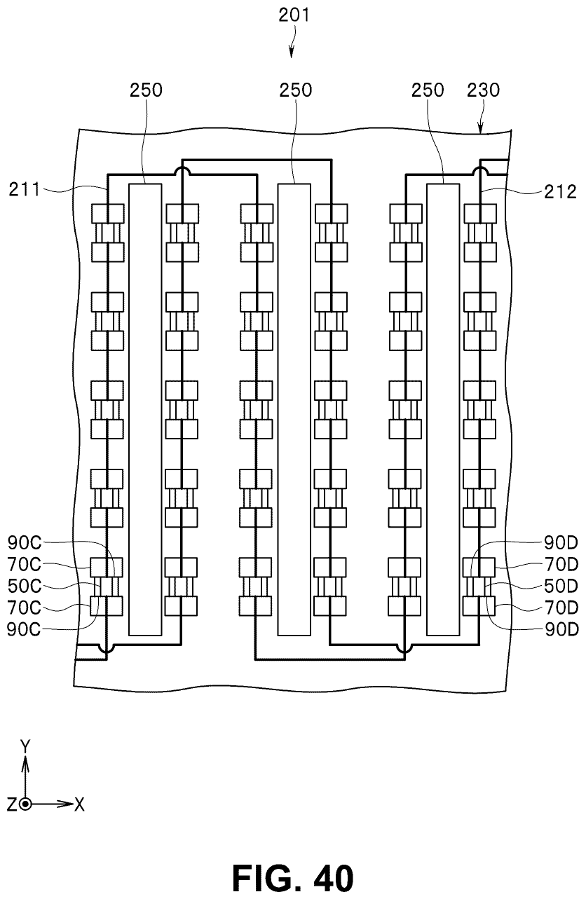

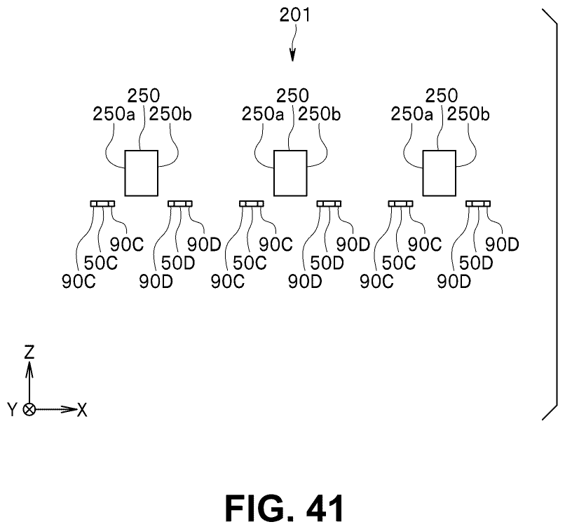

Next, a configuration of the magnetic sensor 201 is specifically described with reference to FIGS. 39 through 41. FIG. 39 is a perspective view showing a part of the magnetic sensor 201. FIG. 40 is a plan view showing the part of the magnetic sensor 201. FIG. 41 is a side view showing the part of the magnetic sensor 201.

The magnetic sensor 201 further includes a substrate 230. The magnetic sensor 201 is constituted by forming a plurality of components other than the substrate 230 on the substrate 230.

The magnetic sensor 201 further includes at least one yoke made of a soft magnetic material. The at least one yoke has a shape long in the Y direction when viewed from the Z direction. The at least one yoke generates a magnetic field component in a direction parallel to the X direction based on the first magnetic field component Hz shown in FIG. 37.

As shown in FIGS. 39 through 41, in the example embodiment in particular, the magnetic sensor 201 includes, as the at least one yoke, a plurality of yokes 250 disposed to be arranged in the X direction. Each of the plurality of yokes 250 has, for example, a rectangular parallelepiped shape long in the Y direction. The plurality of yokes 250 have a same shape. Each of the plurality of yokes 250 has a first end surface 250a and a second end surface 250b located at both ends in a direction parallel to the X direction. In each of the plurality of yokes 250, the first end surface 250a is located at an end in the −X direction and the second end surface 250b is located at an end in the X direction.

Each of the plurality of MR elements 50 is disposed at a position where a magnetic field component generated by the plurality of yokes 250 is applied thereto. In the example embodiment in particular, each of the MR elements 50 is disposed in the vicinity of an end portion of each of the plurality of yokes 250 in the −Z direction. The plurality of MR elements 50 are disposed such that a group of the plurality of MR elements 50 are arranged along the first end surface 250a or the second end surface 250b of each of the plurality of yokes 250. Hereinafter, of the plurality of MR elements 50, a plurality of MR elements arranged along the first end surface 250a are denoted by reference numeral 50C, and the plurality of MR elements arranged along the second end surface 250b are denoted by reference numeral 50D. The direction of the magnetic field component received by the plurality of MR elements 50C and the direction of the magnetic field component received by the plurality of MR elements 50D are opposite to each other.

The plurality of MR elements 50C and the plurality of MR elements 50D may or may not overlap the plurality of yokes 250 when viewed from the Z direction. In the examples shown in FIGS. 39 through 41, the plurality of MR elements 50C and the plurality of MR elements 50D are disposed so as not to overlap the plurality of yokes 250 when viewed from the Z direction.

As shown in FIGS. 39 and 40, of the plurality of magnetic field generators 70, a plurality of magnetic field generators disposed with an MR element 50C interposed therebetween is denoted by reference numeral 70C, and a plurality of magnetic field generators disposed with an MR element 50D interposed therebetween is denoted by reference numeral 70D. The magnetic sensor 201 further includes a plurality of yokes 90C and a plurality of yokes 90D, each including a magnetic layer made of a soft magnetic material. The plurality of yokes 90C include a plurality of pairs of the plurality of yokes 90C, each pair including two yokes 90C. The above two yokes 90C are disposed on both sides of one MR element 50C in a direction parallel to the X direction. The plurality of yokes 90D includes a plurality of pairs of the plurality of yokes 90D, each pair including two yokes 90D. The above two yokes 90D are disposed on both sides of one MR element 50D in a direction parallel to the X direction.

The plurality of yokes 90C have a function of guiding magnetic field components generated by the plurality of yokes 250 to the plurality of MR elements 50C. The plurality of yokes 90D have a function of guiding the magnetic field components generated by the plurality of yokes 250 to the plurality of MR elements 50D.

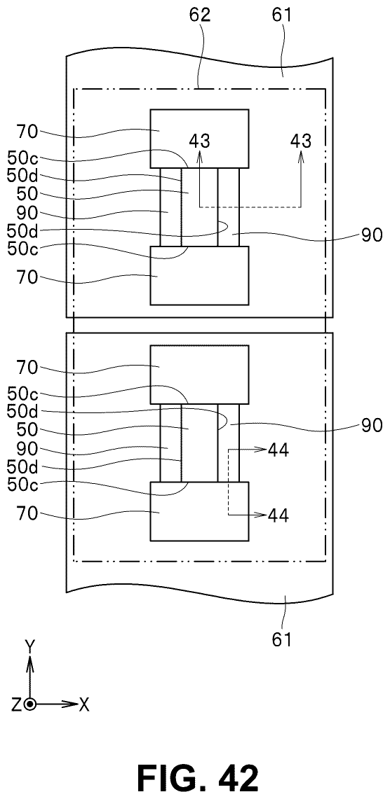

The magnetic sensor 201 further includes a wiring portion 211 electrically connecting the plurality of MR elements 50C and a wiring portion 212 electrically connecting the plurality of MR elements 50D. Each of the wiring portions 211 and 212 is constituted of the plurality of lower electrodes 61 and the plurality of upper electrodes 62, and the plurality of connecting electrodes. Note that the lower electrode 61 and the upper electrode 62 are shown in FIGS. 42 through 44, which will be described later.

The wiring portion 211 includes a first wiring electrically connecting the plurality of MR elements 50C in which the direction of the main component of the magnetization of the magnetization pinned layer 52 is the X direction, and a second wiring electrically connecting the plurality of MR elements 50C in which the direction of the main component of the magnetization of the magnetization pinned layer 52 is the −X direction. The resistor section R31 is constituted of the plurality of MR elements 50C electrically connected by the first wiring. The resistor section R32 is constituted of the plurality of MR elements 50C electrically connected by the second wiring.

The wiring portion 212 includes a third wiring electrically connecting the plurality of MR elements 50D in which the direction of the main component of the magnetization of the each magnetization pinned layer 52 is the −X direction, and a fourth wiring electrically connecting the plurality of MR elements 50D in which the direction of the main component of the magnetization of the each magnetization pinned layer 52 is the X direction. The resistor section R33 is constituted of the plurality of MR elements 50D electrically connected by the third wiring. The resistor section R34 is constituted of the plurality of MR elements 50D electrically connected by the fourth wiring.

Next, an operation of the magnetic sensor 201 is described. In a state where a first magnetic field component Hz is not present and consequently magnetic field components generated by the plurality of yokes 250 are also not present, the magnetization direction of the free layer 54 of each of the plurality of MR elements 50C and the plurality of MR elements 50D is a direction parallel to the Y direction.

When the direction of the first magnetic field component Hz is the Z direction, the direction of the magnetic field component received by each of the plurality of MR elements 50C constituting the resistor sections R31 and R32 is the X direction, and the direction of the magnetic field component received by each of the plurality of MR elements 50D constituting the resistor sections R33 and R34 is the −X direction. In this case, the magnetization direction of the free layer 54 of each of the plurality of MR elements 50C is inclined from a direction parallel to the Y direction toward the X direction, and the magnetization direction of the free layer 54 of each of the plurality of MR elements 50D is inclined from a direction parallel to the Y direction toward the −X direction. As a result, compared to a state in which no magnetic field component is present, the resistance value of each of the plurality of MR elements 50C constituting the resistor section R31 and the resistance value of each of the plurality of MR elements 50D constituting the resistor section R33 decrease, and the resistance value of each of the plurality of MR elements 50C constituting the resistor section R32 and the resistance value of each of the plurality of MR elements 50D constituting the resistor section R34 increase. As a result, the resistance values of the resistor sections R31 and R33 decrease and the resistance values of the resistor sections R32 and R34 increase.

If the direction of the first magnetic field component Hz is the −Z direction, the direction of the magnetic field component and the change in the resistance value of each of the resistor sections R31 to R34 are opposite to the above-mentioned case where the direction of the first magnetic field component Hz is the Z direction.

The amount of change in the resistance value of each of the resistor sections R31 to R34 depends on the strength of the magnetic field component received by each of the plurality of MR elements 50C and the plurality of MR elements 50D. When the strength of the magnetic field component increases, the resistance value of each of the resistor sections R31 to R34 changes such that the amount of increase or the amount of decrease of the resistance value becomes larger. When the strength of the magnetic field component becomes smaller, the resistance value of each of the resistor sections R31 to R34 changes such that the amount of increase or the amount of decrease of the resistance value becomes smaller. The strength of the magnetic field component depends on the strength of the first magnetic field component Hz.

Thus, when the direction and strength of the first magnetic field component Hz change, the resistance value of each of the resistor sections R31 to R34 changes such that either the resistance value of each of the resistor sections R31 and R33 increases and the resistance value of each of the resistor sections R32 and R34 decreases, or the resistance value of each of the resistor sections R31 and R33 decreases and the resistance value of each of the resistor sections R32 and R34 increases. This changes the potential of the connection point between the resistor sections R31 and R32, i.e., the potential of the output port E31, and the potential of the connection point between the resistor sections R33 and R34, i.e., the potential of the output port E32. The magnetic sensor 201 may generate a signal corresponding to the potential of the output port E31 and a signal corresponding to the potential of the output port E32, each as a detection signal. Alternatively, the magnetic sensor 201 may generate a signal corresponding to the potential difference between the output ports E31 and E32 as a detection signal. In this case, the magnetic sensor 201 may further include a differential amplifier (difference detector) that outputs the signal corresponding to the potential difference between the output ports E31 and E32 as a detection signal.

The magnetic sensor system 200 may further include the processor 2 shown in FIGS. 1 and 2 in the first example embodiment. The processor 2 may be configured to receive one detection signal or two detection signals output from the magnetic sensor 201 to generate a detection value having a correspondence with the strength of the first magnetic field component Hz or a detection value having a correspondence with the position of the magnetic field generation section 202 (see FIG. 37).

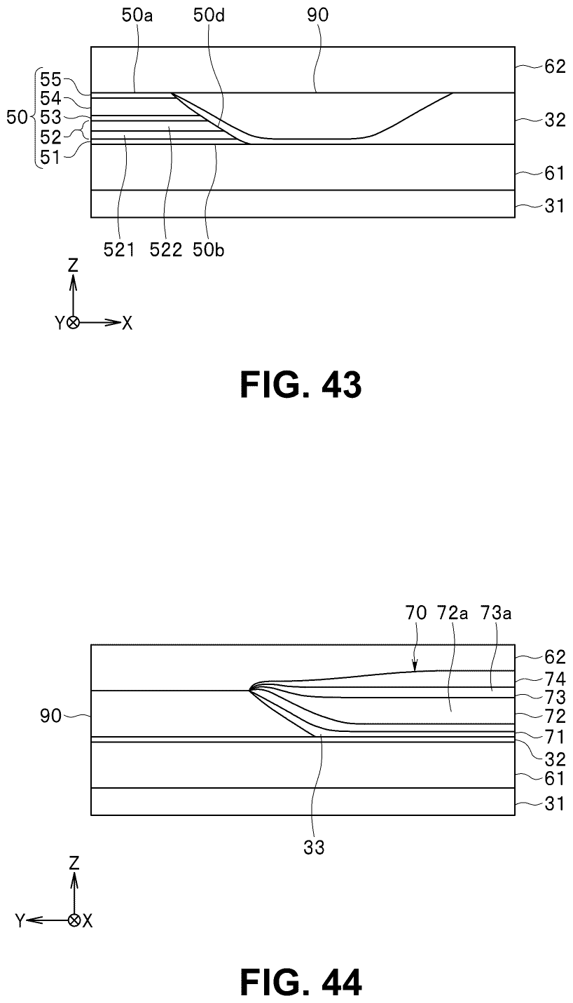

Next, the plurality of yokes 90C and the plurality of yokes 90D are described in detail with reference to FIGS. 42 through 44. FIG. 42 is a plan view showing a main part of the magnetic sensor 201. FIG. 43 is a cross-sectional view showing a part of a cross section at a position indicated by a 43-43 line in FIG. 42. FIG. 44 is a cross-sectional view showing a part of a cross section at a position indicated by a 44-44 line in FIG. 42.

Hereinafter, any yoke of the plurality of yokes 90C and the plurality of yokes 90D is denoted using reference numeral 90. The configuration and shape of each of the MR element 50 and the magnetic field generator 70, and the positional relationship between the MR element 50 and the magnetic field generator 70 are the same as in the third example embodiment.

Here, a configuration of a yoke 90 is described with a focus on one MR element 50. Two yokes 90 are disposed on both sides of the MR element 50 in a direction parallel to the X direction. The two yokes 90 are embedded in the insulating layer 32. The insulating layer 32 is interposed between the MR element 50 and the two yokes 90 and between the lower electrode 61 and the two yokes 90. Each of the two yokes 90 may include, in addition to the magnetic layer, a buffer layer interposed between the magnetic layer and the insulating layer 32, and a cap layer disposed on the magnetic layer. The buffer layer and the cap layer may be formed of a nonmagnetic metallic material, for example. Each of the two yokes 90 is disposed to ride up on the side surface 50d of the MR element 50. A part of each of the two yokes 90 overlaps a part of the MR element 50 when viewed from the Z direction.

The two yokes 90 are disposed between the two magnetic field generators 70, which are disposed at a predetermined distance from each other in a direction parallel to the Y direction. The ferromagnetic layer 72a of the magnetic field generator 70 is disposed to overlap the two yokes 90 when viewed from the Y or −Y direction.

The ferromagnetic layer 72a is disposed to ride up on the yoke 90. A part of the ferromagnetic layer 72a overlaps a part of the yoke 90 when viewed from the Z direction. The insulating layer 33 is interposed between the ferromagnetic layer 72a and the yoke 90. A part of the buffer layer 71 of the magnetic field generator 70 is interposed between the ferromagnetic layer 72a and the insulating layer 33.

In the example embodiment, the upper electrode 62 is disposed on the MR element 50, the two magnetic field generators 70, the two yokes 90, and the insulating layer 32.

Note that the configuration of the magnetic field generator 70 in the example embodiment is not limited to the examples shown in FIGS. 39, 40, 42, and 44. The magnetic sensor 201 according to the example embodiment may include a plurality of magnetic field generators having the same configuration as that of any of the first, second, third, and fourth example embodiments, instead of the plurality of magnetic field generators 70 in the example embodiment. The configuration, operation, and effects of the present example embodiment are otherwise the same as those of any of the first to four example embodiments.

The technology is not limited to the foregoing example embodiments, and various modifications may be made thereto. For example, the magnetic sensor of the technology may be a magnetic sensor including the first and second detection circuits 10 and 20 in the first example embodiment, and the magnetic sensor 201 according to the fifth example embodiment as a third detection circuit. In this magnetic sensor, the third detection circuit (magnetic sensor 201) may be configured to detect a component in a direction parallel to the Z direction of the target magnetic field. This magnetic sensor may be a geomagnetic sensor that detects the geomagnetism as the target magnetic field.

The MR element 50 may be constituted of the buffer layer 51, the free layer 54, the gap layer 53, the magnetization pinned layer 52, and the cap layer 55 stacked in this order from the lower electrode 61 side.

The modification example of the magnetic sensor 1 according to the third example embodiment is not limited to the third example embodiment, and may be applied to example embodiments other than the third example embodiment.

In a case where a first magnetic field generator including a ferromagnetic portion having a magnetization in the first direction and a second magnetic field generator including a ferromagnetic portion having a magnetization in a second direction different from the first direction are to be formed in this order, when the first initial magnetic field generator that later becomes the first magnetic field generator is irradiated with laser light, the second initial magnetic field generator that later becomes the second magnetic field generator may also be irradiated with the laser light. In this case, after fixing the magnetization direction of the ferromagnetic portion of the first magnetic field generator, only the second initial magnetic field generator is irradiated with the laser light to fix the magnetization direction of the ferromagnetic portion of the second magnetic field generator.

As described above, a magnetic sensor manufactured by a manufacturing method according to one embodiment of the technology includes: at least one magnetoresistive element including a magnetization pinned layer, a direction of a magnetization of the magnetization pinned layer being pinned in a certain direction, the magnetization including a component in a first direction, and a free layer whose magnetization direction is variable depending on a target magnetic field, the target magnetic field being a magnetic field to be detected; and at least one magnetic field generator including a ferromagnetic portion including a ferromagnetic material, a direction of a magnetization of the ferromagnetic portion being fixed in a certain direction, the magnetization including a component in a second direction different from the first direction, and an antiferromagnetic portion including an antiferromagnetic material and exchange-coupled with the ferromagnetic portion, the at least one magnetic field generator being configured to generate a magnetic field to be applied to the at least one magnetoresistive element. The manufacturing method of a magnetic sensor according to one embodiment of the technology includes a process of forming the at least one magnetoresistive element, and a process of forming the at least one magnetic field generator. The process of forming the at least one magnetic field generator includes a process of forming at least one initial magnetic field generator including an initial ferromagnetic portion that later becomes the ferromagnetic portion and the antiferromagnetic portion, and a process of fixing a magnetization direction of the initial ferromagnetic portion so that the initial ferromagnetic portion becomes the ferromagnetic portion by using laser light and a first external magnetic field including a component in a first magnetic field direction. The first magnetic field direction may coincide with the second direction.

In the manufacturing method of a magnetic sensor according to one embodiment of the technology, the process of forming the at least one magnetoresistive element may include a process of forming at least one initial magnetoresistive element including an initial magnetization pinned layer that later becomes the magnetization pinned layer and the free layer, and a process of fixing a magnetization direction of the initial magnetization pinned layer so that the initial magnetization pinned layer becomes the magnetization pinned layer by using laser light and a second external magnetic field including a component in a second magnetic field direction. The second magnetic field direction may coincide with the first direction. The process of fixing the magnetization direction of the initial magnetization pinned layer may be performed before the process of fixing the magnetization direction of the initial ferromagnetic portion.

In the manufacturing method of a magnetic sensor according to one embodiment of the technology, the magnetization pinned layer may include a first ferromagnetic layer including a ferromagnetic material, a second ferromagnetic layer including a ferromagnetic material, a nonmagnetic layer including a nonmagnetic metallic material and interposed between the first ferromagnetic layer and the second ferromagnetic layer, and an antiferromagnetic layer including an antiferromagnetic material and in contact with the first ferromagnetic layer. A magnetization amount per unit area of the first ferromagnetic layer may be less than or equal to a magnetization amount per unit area of the second ferromagnetic layer.

In the manufacturing method of a magnetic sensor according to one embodiment of the technology, the magnetization pinned layer may include a ferromagnetic layer including a ferromagnetic material and an antiferromagnetic layer including an antiferromagnetic material and in contact with the ferromagnetic layer. The antiferromagnetic portion and the antiferromagnetic layer may contain at least one same element.

In the manufacturing method of a magnetic sensor according to one embodiment of the technology, in the process of fixing the magnetization direction of the initial ferromagnetic portion, the at least one magnetoresistive element may not be irradiated with the laser light. Alternatively, in the process of fixing the magnetization direction of the initial ferromagnetic portion, the at least one magnetoresistive element may be irradiated with the laser light.

The manufacturing method of a magnetic sensor according to one embodiment of the technology may further include, after the process of fixing the magnetization direction of the initial ferromagnetic portion, a process of performing an annealing process that heats, at a predetermined temperature, a stack including the at least one magnetoresistive element and the at least one magnetic field generator.

In the manufacturing method of a magnetic sensor according to one embodiment of the technology, the at least one magnetoresistive element may include a first magnetoresistive element and a second magnetoresistive element. The at least one magnetic field generator may include a first magnetic field generator configured to generate a magnetic field to be applied to the first magnetoresistive element and a second magnetic field generator configured to generate a magnetic field to be applied to the second magnetoresistive element. Between a set of the first magnetoresistive element and the first magnetic field generator and a set of the second magnetoresistive element and the second magnetic field generator, no other set of another magnetoresistive element capable of detecting magnetoresistive effect and another magnetic field generator may be interposed. The direction of the magnetization of the ferromagnetic portion of the first magnetic field generator and the direction of the magnetization of the ferromagnetic portion of the second magnetic field generator may be different from each other. The process of forming the at least one magnetic field generator may be a process of forming the first magnetic field generator and the second magnetic field generator. The process of forming the at least one initial magnetic field generator may be a process of forming a first initial magnetic field generator and a second initial magnetic field generator, the first initial magnetic field generator including a first initial ferromagnetic portion that later becomes the ferromagnetic portion of the first magnetic field generators and the antiferromagnetic portion of the first magnetic field generator, and the second initial magnetic field generator including a second initial ferromagnetic portion that later becomes the ferromagnetic portion of the second magnetic field generators and the antiferromagnetic portion of the second magnetic field generator. The process of fixing the magnetization direction of the initial ferromagnetic portion may be a process of fixing a magnetization direction of the first initial ferromagnetic portion and a magnetization direction of the second initial ferromagnetic portion by irradiating the first initial magnetic field generator and the second initial magnetic field generator with the laser light in this order. A temperature of the ferromagnetic portion of the first initial magnetic field generator may not rise to be equal to or higher than a blocking temperature while the second initial magnetic field generator is irradiated with the laser light.

In the manufacturing method of a magnetic sensor according to one embodiment of the technology, the at least one magnetoresistive element may include a first magnetoresistive element and a second magnetoresistive element. The at least one magnetic field generator may include a first magnetic field generator configured to generate a magnetic field to be applied to the first magnetoresistive element and a second magnetic field generator configured to generate a magnetic field to be applied to the second magnetoresistive element. The direction of the magnetization of the ferromagnetic portion of the first magnetic field generator may be the same as the direction of the magnetization of the ferromagnetic portion of the second magnetic field generator. The process of forming the at least one magnetic field generator may be a process of forming the first magnetic field generator and the second magnetic field generator. The process of forming the at least one initial magnetic field generator may be a process of forming a first initial magnetic field generator and a second initial magnetic field generator, the first initial magnetic field generator including a first initial ferromagnetic portion that later becomes the ferromagnetic portion of the first magnetic field generators and the antiferromagnetic portion of the first magnetic field generator, and the second initial magnetic field generator including a second initial ferromagnetic portion that later becomes the ferromagnetic portion of the second magnetic field generators and the antiferromagnetic portion of the second magnetic field generator. The process of fixing the magnetization direction of the initial ferromagnetic portion may be a process of fixing a magnetization direction of the first initial ferromagnetic portion and a magnetization direction of the second initial ferromagnetic portion by irradiating the first initial magnetic field generator and the second initial magnetic field generator simultaneously with the laser light.

In the manufacturing method of a magnetic sensor according to one embodiment of the technology, the at least one magnetoresistive element may include a plurality of magnetoresistive elements. The at least one magnetic field generator may include a plurality of magnetic field generators. The process of forming the at least one magnetic field generator may be a process of forming the plurality of magnetic field generators. The process of forming the at least one initial magnetic field generator may be a process of forming a plurality of initial magnetic field generators each including the initial ferromagnetic portion that later becomes the ferromagnetic portion and the antiferromagnetic portion. The process of fixing the magnetization direction of the initial ferromagnetic portion may be a process of fixing the magnetization direction of the initial ferromagnetic portion of each of the plurality of initial magnetic field generators by irradiating one or more of the plurality of initial magnetic field generators with the laser light in order.

In the manufacturing method of a magnetic sensor of the technology, a magnetization direction of the initial ferromagnetic portion is fixed so that the initial ferromagnetic portion becomes the ferromagnetic portion by using laser light and a first external magnetic field including a component in a first magnetic field direction. According to the technology, this enables the magnetization direction of the free layer of the at least one magnetoresistive element to be different.

It is apparent that the technology can be carried out in various forms and modifications in the light of the foregoing descriptions. Accordingly, within the scope of the following claims and equivalents thereof, the technology can be carried out in forms other than the foregoing example embodiments.

1. A manufacturing method of a magnetic sensor, the magnetic sensor comprising:
at least one magnetoresistive element including: a magnetization pinned layer, a direction of a magnetization of the magnetization pinned layer being pinned in a certain direction, the magnetization including a component in a first direction; and a free layer whose magnetization direction is variable depending on a target magnetic field, the target magnetic field being a magnetic field to be detected; and
at least one magnetic field generator including: a ferromagnetic portion including a ferromagnetic material, a direction of a magnetization of the ferromagnetic portion being fixed in a certain direction, the magnetization including a component in a second direction different from the first direction; and an antiferromagnetic portion including an antiferromagnetic material and exchange-coupled with the ferromagnetic portion, the at least one magnetic field generator being configured to generate a magnetic field to be applied to the at least one magnetoresistive element, the method comprising:
a process of forming the at least one magnetoresistive element; and
a process of forming the at least one magnetic field generator, wherein
the process of forming the at least one magnetic field generator includes:
a process of forming at least one initial magnetic field generator including an initial ferromagnetic portion that later becomes the ferromagnetic portion and the antiferromagnetic portion; and
a process of fixing a magnetization direction of the initial ferromagnetic portion so that the initial ferromagnetic portion becomes the ferromagnetic portion by using laser light and a first external magnetic field including a component in a first magnetic field direction.

2. The manufacturing method of a magnetic sensor according to claim 1, wherein the process of forming the at least one magnetoresistive element includes:
a process of forming at least one initial magnetoresistive element including an initial magnetization pinned layer that later becomes the magnetization pinned layer and the free layer; and
a process of fixing a magnetization direction of the initial magnetization pinned layer so that the initial magnetization pinned layer becomes the magnetization pinned layer by using laser light and a second external magnetic field including a component in a second magnetic field direction.

3. The manufacturing method of a magnetic sensor according to claim 2, wherein the process of fixing the magnetization direction of the initial magnetization pinned layer is performed before the process of fixing the magnetization direction of the initial ferromagnetic portion.

4. The manufacturing method of a magnetic sensor according to claim 1, wherein
the magnetization pinned layer includes a first ferromagnetic layer including a ferromagnetic material, a second ferromagnetic layer made of a ferromagnetic material, a nonmagnetic layer including a nonmagnetic metallic material and interposed between the first ferromagnetic layer and the second ferromagnetic layer, and an antiferromagnetic layer including an antiferromagnetic material and in contact with the first ferromagnetic layer.

5. The manufacturing method of a magnetic sensor according to claim 4, wherein a magnetization amount per unit area of the first ferromagnetic layer is less than or equal to a magnetization amount per unit area of the second ferromagnetic layer.

6. The manufacturing method of a magnetic sensor according to claim 1, wherein
the magnetization pinned layer includes a ferromagnetic layer including a ferromagnetic material and an antiferromagnetic layer including an antiferromagnetic material and in contact with the ferromagnetic layer, and
the antiferromagnetic portion and the antiferromagnetic layer contain at least one same element.

7. The manufacturing method of a magnetic sensor according to claim 1, wherein
in the process of fixing the magnetization direction of the initial ferromagnetic portion, the at least one magnetoresistive element is not irradiated with the laser light.

8. The manufacturing method of a magnetic sensor according to claim 1, wherein
in the process of fixing the magnetization direction of the initial ferromagnetic portion, the at least one magnetoresistive element is irradiated with the laser light.

9. The manufacturing method of a magnetic sensor according to claim 1, further comprising, after the process of fixing the magnetization direction of the initial ferromagnetic portion, a process of performing an annealing process that heats, at a predetermined temperature, a stack including the at least one magnetoresistive element and the at least one magnetic field generator.

10. The manufacturing method of a magnetic sensor according to claim 1, wherein
the at least one magnetoresistive element comprises a first magnetoresistive element and a second magnetoresistive element,
the at least one magnetic field generator comprises a first magnetic field generator configured to generate a magnetic field to be applied to the first magnetoresistive element and a second magnetic field generator configured to generate a magnetic field to be applied to the second magnetoresistive element,
between a set of the first magnetoresistive element and the first magnetic field generator and a set of the second magnetoresistive element and the second magnetic field generator, no other set of another magnetoresistive element capable of detecting magnetoresistive effect and another magnetic field generator is interposed, and
the direction of the magnetization of the ferromagnetic portion of the first magnetic field generator and the direction of the magnetization of the ferromagnetic portion of the second magnetic field generator are different from each other.

11. The manufacturing method of a magnetic sensor according to claim 10, wherein
the process of forming the at least one magnetic field generator is a process of forming the first magnetic field generator and the second magnetic field generator,
the process of forming the at least one initial magnetic field generator is a process of forming a first initial magnetic field generator and a second initial magnetic field generator, the first initial magnetic field generator including a first initial ferromagnetic portion that later becomes the ferromagnetic portion of the first magnetic field generators and the antiferromagnetic portion of the first magnetic field generator, and the second initial magnetic field generator including a second initial ferromagnetic portion that later becomes the ferromagnetic portion of the second magnetic field generators and the antiferromagnetic portion of the second magnetic field generator,
the process of fixing the magnetization direction of the initial ferromagnetic portion is a process of fixing a magnetization direction of the first initial ferromagnetic portion and a magnetization direction of the second initial ferromagnetic portion by irradiating the first initial magnetic field generator and the second initial magnetic field generator with the laser light in this order, and
a temperature of the ferromagnetic portion of the first initial magnetic field generator does not rise to be equal to or higher than a blocking temperature while the second initial magnetic field generator is irradiated with the laser light.

12. The manufacturing method of a magnetic sensor according to claim 1, wherein
the at least one magnetoresistive element comprises a first magnetoresistive element and a second magnetoresistive element,
the at least one magnetic field generator comprises a first magnetic field generator configured to generate a magnetic field to be applied to the first magnetoresistive element and a second magnetic field generator configured to generate a magnetic field to be applied to the second magnetoresistive element,
the direction of the magnetization of the ferromagnetic portion of the first magnetic field generator is the same as the direction of the magnetization of the ferromagnetic portion of the second magnetic field generator,
the process of forming the at least one magnetic field generator is a process of forming the first magnetic field generator and the second magnetic field generator,
the process of forming the at least one initial magnetic field generator is a process of forming a first initial magnetic field generator and a second initial magnetic field generator, the first initial magnetic field generator including a first initial ferromagnetic portion that later becomes the ferromagnetic portion of the first magnetic field generators and the antiferromagnetic portion of the first magnetic field generator, and the second initial magnetic field generator including a second initial ferromagnetic portion that later becomes the ferromagnetic portion of the second magnetic field generators and the antiferromagnetic portion of the second magnetic field generator, and
the process of fixing the magnetization direction of the initial ferromagnetic portion is a process of fixing a magnetization direction of the first initial ferromagnetic portion and a magnetization direction of the second initial ferromagnetic portion by irradiating the first initial magnetic field generator and the second initial magnetic field generator simultaneously with the laser light.

13. The manufacturing method of a magnetic sensor according to claim 1, wherein
the at least one magnetoresistive element comprises a plurality of magnetoresistive elements,
the at least one magnetic field generator comprises a plurality of magnetic field generators,
the process of forming the at least one magnetic field generator is a process of forming the plurality of magnetic field generators,
the process of forming the at least one initial magnetic field generator is a process of forming a plurality of initial magnetic field generators each including the initial ferromagnetic portion that later becomes the ferromagnetic portion and the antiferromagnetic portion, and
the process of fixing the magnetization direction of the initial ferromagnetic portion is a process of fixing the magnetization direction of the initial ferromagnetic portion of each of the plurality of initial magnetic field generators by irradiating one or more of the plurality of initial magnetic field generators with the laser light in order.
